(19) United States
(12) Patent Application Publication
(10) Pub. No.: US 2015/0311297 A1
(43) Pub. Date: Oct. 29, 2015

(54) SEMICONDUCTOR DEVICE AND METHOD OF FORMING THEREOF

(71) Applicant: Samsung Electronics Co., Ltd., Suwon-Si (KR)

(72) Inventors: Badro IM, Yongin-si (KR); Ki-Vin IM, Seongnam-si (KR); Young-kuk KIM, Seoul (KR); Han-jin LIM, Seoul (KR); In-Seak HWANG, Suwon-si (KR)

(21) Appl. No.: 14/556,870

(22) Filed: Dec. 1, 2014

(30) Foreign Application Priority Data
Apr. 24, 2014 (KR) 10-2014-0049345

(51) Int. Cl. H01L 29/423; H01L 29/06; H01L 29/10

(52) U.S. Cl. CPC H01L 29/4236; H01L 29/1033; H01L 29/0653

(57) ABSTRACT

Provided are a semiconductor device and a method of forming thereof. The semiconductor device includes a substrate having an isolating trench defining active areas, gate structures formed in the active area and crossing the isolating trench, a first protection layer formed on the active area of the substrate, and a second protection layer formed on the first protection layer, wherein, in a first isolating area in which the gate structure and the isolating trench cross, the first protection layer is conformally formed on an inner wall and bottom of the isolating trench, and the second protection layer is formed on the first protection layer formed on the bottom of the isolating trench.

### CROSS-REFERENCE TO RELATED APPLICATION

This application claims priority under 35 U.S.C. §119 to Korean Patent Application No. 10-2014-0049345 filed on Apr. 24, 2014, the disclosure of which is hereby incorporated by reference in its entirety.

### BACKGROUND

1. Technical Field

Example embodiments of the inventive concepts relate to a semiconductor device and a method of forming thereof.

2. Description of Related Art

In high integration of semiconductor devices, it is difficult to ensure stable operations of transistors. A buried channel array transistor (BCAT) is being studied as a device overcoming a problem such as a short channel effect and reducing the transistor. A semiconductor device including a gate structure being buried in a substrate is being studied for improving a degree of integration of the semiconductor device.

### SUMMARY

Example embodiments of the inventive concepts provide a semiconductor device.

Other example embodiments of the inventive concepts provide a method of forming a semiconductor device.

Other example embodiments of the inventive concepts provide a memory module, a memory card, a system, and a mobile wireless phone including the semiconductor device.

In accordance with some example embodiments of the inventive concepts, a semiconductor device may include a substrate having an isolating trench defining active areas, a gate structure formed in the active area and crossing the isolating trench, a first protection layer formed on the active area of the substrate, and a second protection layer formed on the first protection layer, wherein, in a first isolating area in which the gate structure and the isolating trench cross, the first protection layer may be conformally formed on an inner wall and bottom of the isolating trench, and the second protection layer may be formed on the first protection layer formed on the bottom of the isolating trench.

In accordance with some example embodiments of the inventive concepts, a semiconductor device may include a substrate including a cell area and a peripheral area, an isolating trench defining a cell active area in the cell area, and a peripheral active area in the peripheral area, a cell gate structure formed in the cell active area and crossing the isolating trench, a first protection layer conformally formed on an upper surface of the cell active area, and an inner wall and bottom of the isolating trench, a second protection layer formed on the first protection layer on the upper surface of the cell active area and the bottom of the isolating trench, a bit line structure arranged perpendicular to the cell gate structure, and crossing the cell active area; and a peripheral gate line structure configured to cross the peripheral active area.

Details of other example embodiments are included in detailed explanations and the drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. In the drawings:

FIG. 1 is a schematic layout showing a semiconductor device in accordance with some example embodiments of the inventive concepts;

FIG. 2A is a cross-sectional view taken along line I-I′ of FIG. 1 according to some example embodiments;

FIG. 2B is a cross-sectional view taken along line II-IF of FIG. 1 according to some example embodiments;

FIG. 2C is a cross-sectional view taken along line III-III′ of FIG. 1 according to some example embodiments;

FIG. 2D is a cross-sectional view taken along line IV-IV′ of FIG. 1 according to some example embodiments;

FIGS. 3A to 15A, 3B to 15B, 3C to 15C and 3D to 15D are cross-sectional views showing a method of forming a semiconductor device in accordance with some example embodiments of the inventive concepts;

FIGS. 16A to 16D are cross-sectional views showing a semiconductor device in accordance with some example embodiments of the inventive concepts;

FIGS. 17A to 20A, 17B to 20B, 17C to 20C and 17D to 20D are cross-sectional views showing a method of forming a semiconductor device in accordance with some example embodiments of the inventive concepts;

FIG. 21 is a schematic view showing a memory module including the semiconductor device in accordance with some example embodiment of the inventive concepts;

FIG. 22 is a schematic view showing a memory card including the semiconductor device in accordance with some example embodiment of the inventive concepts;

FIGS. 23A and 23B are block diagrams showing a system including the semiconductor device in accordance with some example embodiments of the inventive concepts; and

FIG. 24 is a conceptual view showing a mobile wireless phone including the semiconductor device in accordance with some example embodiments of the inventive concepts.

### DETAILED DESCRIPTION OF EXAMPLE EMBODIMENTS

Various embodiments will now be described more completely with reference to the accompanying drawings in which some example embodiments are shown. These inventive concepts may, however, be embodied in different forms and should not be construed as limited to the embodiments set forth herein. Rather, these example embodiments are provided so that this disclosure is thorough and complete and completely conveys the inventive concepts to those skilled in the art.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected, or coupled to the other element or layer or intervening elements or layers may be present. In the following explanation, the same reference numerals denote the same components throughout the specification. As used herein, the term “and/or” includes any and all combinations of one or more of the associated listed items.

Spatially relative terms, such as “beneath,” “below,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein may be interpreted accordingly.

Some example embodiments of the inventive concepts will be described with reference to cross-sectional views and/or plan views, which are ideal example views. Thicknesses of layers and areas are exaggerated for effective description of the technical contents in the drawings. Forms of the example embodiments may be modified by the manufacturing technology and/or tolerance. Therefore, the example embodiments of the inventive concepts are not intended to be limited to illustrated specific forms, and include modifications of forms generated according to manufacturing processes. For example, an etching area illustrated at a right angle may be round or have a predetermined (or desired) curvature. Therefore, areas illustrated in the drawings have overview properties, and shapes of the areas are illustrated special forms of the areas of a device, and are not intended to be limited to the scope of the inventive concepts.

Hereinafter, like reference numerals in the drawings denote like elements or functionally similar elements. Therefore, although like reference numerals or similar reference numerals are not mentioned or described in the drawing, it will be described with reference to the other drawings. Further, although reference numerals are not illustrated, it will be described with reference to the other drawings.

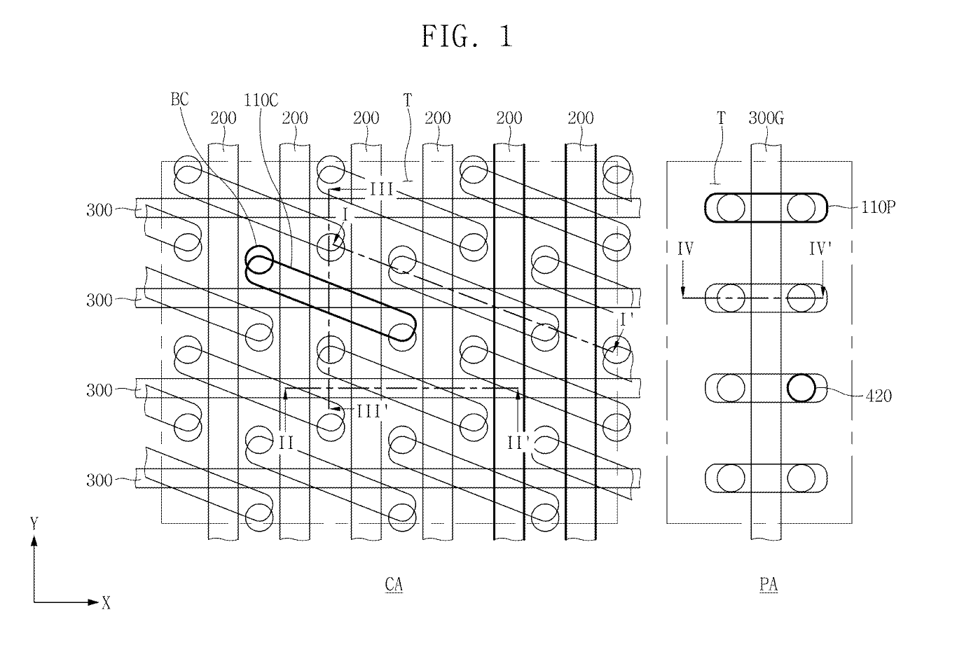

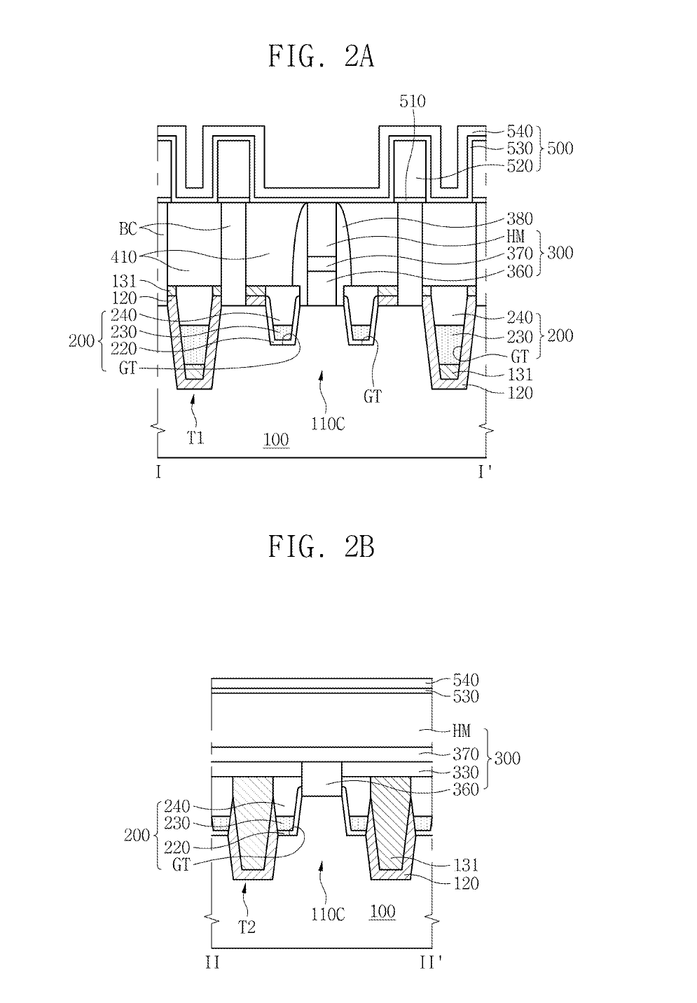

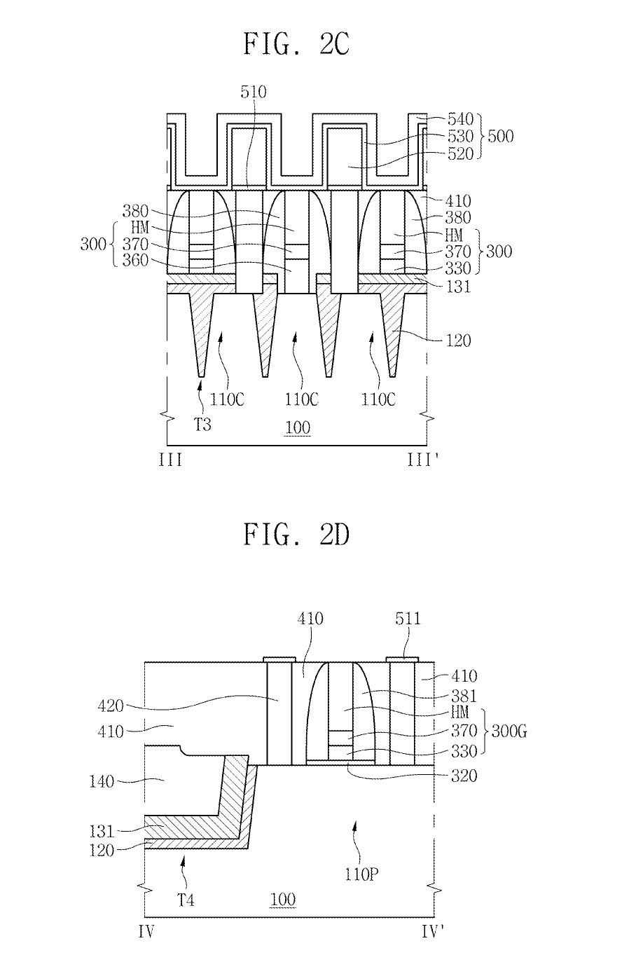

FIG. 1 is a schematic layout showing a semiconductor device in accordance with some example embodiments of the inventive concepts, and FIGS. 2A to 2D are schematic cross-sectional views showing a semiconductor device taken along lines I-I′, II-II′, III-III′, and IV-IV′ of FIG. 1 in accordance with some example embodiments of the inventive concepts.

Referring to FIG. 1, the semiconductor device in accordance with some example embodiments of the inventive concepts may include a substrate 100 having a cell area CA and a peripheral area PA. An isolating trench T may be formed in the substrate 100. The isolating trench T may define cell active areas 110C in a cell area CA, and peripheral active areas 110P in a peripheral area PA. A buried channel array transistor may be formed in the cell area CA. An unburied transistor may be formed in the peripheral area PA. The substrate 100 may include a silicon wafer, a silicon on insulator (SOI) substrate, an SiGe substrate, an SiC substrate, a compound semiconductor substrate, or various semiconductor substrates.

Word lines 200 and bit line structures 300 may be formed in the cell area CA. The word lines 200 may extend in an X direction in the cell area CA. The word lines 200 may cross the isolating trench T and the cell active area 110C. The word line 200 will be described as a cell gate structure in other drawings. Bit line structures 300 may extend in a Y direction in the cell area CA. The bit line structures 300 may cross the isolating trench T and the cell active area 110C. A peripheral gate line structure 300G may be formed in the peripheral area PA. The peripheral gate line structure 300G may cross the isolating trench T and the peripheral active area 110P.

The cell active areas 110C and the peripheral active areas 110P may be isolated from each other. The cell active area 110C and the peripheral active area 100P may be a bar shape. The cell active areas 110C may be arranged to slope with a predetermined (or desired) angle between an X direction and a Y direction. As an example, the cell active areas 110C may be arranged in a Y direction without a slope. An upper portion of the substrate 100 may include doped impurity regions in the cell active areas 110C and the peripheral active areas 110P.

The isolating trench T may include an isolating area T1, an isolating area T2, an isolating area T3 and an isolating area T4. The isolating area T1 may be disposed between the cell active areas 110C in a longitudinal direction of the active area. The isolating area T2 may be disposed between the cell active areas 110C in an X direction. A width of the isolating trench T in the isolating area T1 may be similar to a width of the isolating trench T in the isolating area T2. The isolating area T3 may be disposed between the cell active areas 110C in a Y direction. A width of the isolating trench T in the isolating area T3 may be smaller than the width of the isolating trench T in the isolating areas T1 and T2. The isolating area T4 may be disposed between the cell area CA and the peripheral area PA. A width of the isolating trench T in the isolating are T4 may be greater than the width of the isolating trench T in the isolating areas T1 and T2.

The semiconductor device in accordance with some example embodiments of the inventive concepts may include a protection layer 120 and a protection layer 131. The protection layer 120 may be formed on the substrate 100 in the cell active area 110C. The protection layer 131 may be formed on the protection layer 120. The protection layer 120 and the protection layer 131 may be silicon insulating layers. An insulating characteristic of the protection layer 120 may be different from an insulating characteristic of the protection layer 131. An as example, the protection layer 120 may include a silicon oxide layer, and the protection layer 131 may include a silicon nitride layer.

The protection layer 120 and the protection layer 131 may be formed in the isolating area T1, the isolating area T2, the isolating area T3, and the isolating area T4.

As an example, in the isolating area T1 as shown in FIG. 2A, the protection layer 120 may be conformally formed on an inner wall and bottom of the isolating trench T, and the protection layer 131 may be formed on the protection layer 120 formed on the bottom of the isolating trench T. In the isolating area T2 as shown in FIG. 2B, the protection layer 120 may be conformally formed on the inner wall and bottom of the isolating trench T, and the protection layer 131 may be formed to completely fill the isolating trench T. A level of an upper surface of the protection layer 131 in the isolating area T2 may be same as a level of an upper surface of the protection layer 131 in the isolating area T1. In the isolating area T3 as shown in FIG. 2C, the protection layer 120 may be formed to completely fill the isolating trench T, and the protection layer 131 may be formed on the protection layer 120. A level of an upper surface of the protection layer 120 in the isolating trench T may be same as a level of an upper surface of the protection layer 120 in the cell active area 110C. A level of the upper surface of the protection layer 131 in the isolating trench T may be same as a level of the upper surface of the protection layer 131 in the cell active area 110C. In the isolating area T4 as shown in FIG. 2D, the protection layer 120 may be conformally formed on the inner wall and bottom of the isolating trench T, and the protection layer 131 may be conformally formed on the protection layer 120. The protection layer 131 formed in the isolating area T4 may have a different thickness from the protection layer 131 formed in the cell active area 110C as shown in FIG. 2A or 2C.

The semiconductor device in accordance with some example embodiments of the inventive concepts may include a trench insulating layer 140. The trench insulating layer 140 may be formed on the protection layer 131 to completely fill the isolating trench T in the isolating area T4. The trench insulating layer 140 may include a silicon insulating layer, and the silicon insulating layer may include undoped silicate glass (USG), tonen silazene (TOSZ), or plasma-enhanced tetra ethyl ortho-silicate (PE-TEOS).

The semiconductor device in accordance with some example embodiments of the inventive concepts may include cell gate structures 200. Each of the cell gate structures 200 may be a line shape. The cell gate structures 200 may extend in an X direction. The cell gate structures 200 may cross the cell active area 110C and the isolating trench T in the cell area CA. Each of cell gate structures 200 may include a gate trench GT, a cell gate insulating layer 220, a cell gate line 230, and a gate capping layer 240.

The gate trench GT may cross the isolating trench T and the cell active area 110C. At least two gate trenches GT may be formed in one cell active area 110C. As an example, when the cell active area 110C is formed in a diagonal line shape in a Y direction, the gate trench GT may be formed to cross the cell active area 110C in a diagonal line direction. As an example, when the cell active area 110C is formed in a Y direction, the gate trench GT may be formed to cross perpendicular to the cell active area 110C. The gate trench GT may be cross the isolating trench T in the cell active area 110C. A level of a bottom of the gate trench GT in the cell active area 110C may be different from a level of a bottom of the gate trench GT in the isolating trench T. The gate trench GT may expose side surfaces of an upper portion of the protection layer 131 in the isolating area T2 as shown in FIG. 2B. The gate trench GT may expose the protection layer 120 in the isolating area T2 as shown in FIG. 2B.

The cell gate insulating layer 220 may be formed on the substrate 100. The cell gate insulating layer 220 may be disposed in the gate trench GT. The cell gate insulating layer 220 may include a silicon oxide layer, and the silicon oxide layer may include a thermal or radical oxidized silicon oxide layer.

The cell gate line 230 may be formed to fill a lower portion of the gate trench GT. The cell gate line 230 may be formed on the protection layer 131 in the isolating area T1 as shown in FIG. 2A. The cell gate line 230 may be disposed on the cell gate insulating layer 220 in the cell active area 110C as shown in FIGS. 2A and 2B. A level of an upper surface of the cell gate line 230 may be lower than a level of an upper surface of the substrate 100 in the cell active area 110C. A level of the upper surface of the cell gate line 230 in the isolating area T1 may be same as a level of the upper surface of the cell gate line 230 in the cell active area 110C. The cell gate line 230 may include a metal, a metal silicide, or a conductive thin layer such as doped poly-silicon.

The gate capping layer 240 may be formed to fill an upper portion of the gate trench GT. A level of an upper surface of the gate capping layer 240 may be same as a level of the upper surface of the protection layer 131 in the cell active area 110C. The gate capping layer 240 may include a silicon insulating layer having an etch rate the same as or similar to the protection layer 131. The gate capping layer 240 may include a silicon nitride layer, or a silicon oxynitride layer.

The semiconductor device in accordance with some example embodiments of the inventive concepts may include the bit line structures 300. The bit line structures 300 may be disposed in the cell area CA. The bit line structures 300 may extend in a Y direction. The bit line structures 300 may cross the isolating trench T and the cell active area 110C. The bit line structures 300 may be arranged perpendicular to the cell gate structures 200.

Each of the bit line structures 300 may include a conductive layer 330, a bit line contact plug 360, a conductive layer 370 and a hard mask HM. The conductive layer 330 may extend in X direction. The bit line contact plug 360 may be disposed on the conductive layer 330. The bit line contact plug 360 may contact the cell active area 110C. The bit line contact plug 360 may penetrate the conductive layer 330 on the cell active area 110C. The conductive layer 370 disposed on the conductive layer 330 and the bit line contact plug 360. The hard mask HM disposed on the conductive layer 370. The conductive layers 330 of the bit line structures 300 may be disposed on the protection layer 131 in the isolating area T3, as shown in FIG. 2C. The conductive layer 330 may include doped polysilicon, a metal silicide, or a metal. The bit line contact plug 360 may include single-crystalline silicon grown by an epitaxial method, doped polysilicon, a metal silicide, or a metal. The conductive layer 370 may include doped polysilicon, a metal silicide, or a metal. The hard mask HM may be a silicon insulating layer, such as a silicon nitride layer.

The semiconductor device in accordance with some example embodiments of the inventive concepts may include a peripheral gate insulating layer 320 and a peripheral gate line structure 300G. The peripheral gate insulating layer 320 may be formed on the substrate 100 in the peripheral area PA. The peripheral gate line structure 300G may cross the peripheral active area 110P of the peripheral area PA. The peripheral gate line structure 300G may be formed on the peripheral gate insulating layer 320. The peripheral gate line structure 300G may be a line shape passing through an upper portion of the isolating trench T in the peripheral area PA. The peripheral gate insulating layer 320 may include a silicon oxide layer such as a thermal or radical oxidized silicon oxide layer. The peripheral gate line structure 300G may be formed as a structure in which the conductive layer 330, the conductive layer 370, and the hard mask HM are stacked.

The semiconductor device in accordance with some example embodiments of the inventive concepts may include spacers 380, spacers 381, an insulating layer 410, storage contacts BC, and source/drain contacts 420.

The spacers 380 may be formed on side surfaces of the bit line structure 300. The spacers 381 may be formed on side surfaces of the peripheral gate line structure 300G. The spacers 380 and the spacers 381 may be a silicon insulating layer such as a silicon oxide layer, a silicon nitride layer, or a multi-layer structure of a silicon oxide layer and a silicon nitride layer.

The insulating layer 410 may be formed on the substrate 100 in the cell area CA. The insulating layer 410 may be formed on the protection layer 131 and the gate capping layer 240. The insulating layer 410 may be disposed on the substrate 100 in the peripheral active area 110P in the peripheral area PA. A level of an upper surface of the insulating layer 410 may be same as a level of an upper surface of the bit line structure 300. The upper surface of the insulating layer 410 may be same as an upper surface of the hard mask HM of the bit line structure 300. The level of the upper surface of the insulating layer 410 may be same as a level of an upper surface of the peripheral gate line structure 300G. The level of the upper surface of the insulating layer 410 may be same as a level of an upper surface of the hard mask HM of the peripheral gate line structure 300G.

The storage contacts BC may be formed in the insulating layer 410 in the cell area CA. Each of the storage contact BC may be disposed between the bit line structures 300. The storage contacts BC may be connected to the substrate 100 in the cell active area 110C. The storage contacts BC may include a region overlapping the isolating area T3 shown in FIG. 2C.

The source/drain contacts 420 may be formed in the insulating layer 410 in the peripheral area PA. The source/drain contacts 420 may connect to the substrate 100 in the peripheral active area 110P.

The semiconductor device in accordance with some example embodiments of the inventive concepts may include contact pads 510, contact pads 511 and information storage elements 500. The contact pads 510 may be connected to the storage contacts BC. The contact pads 511 may be connected to the source/drain contacts 420. The information storage elements 500 may be formed on the insulating layer 410 in the cell area CA. The information storage elements 500 may be disposed on the contact pads 510.

The information storage element 500 may include a capacitor. The information storage element 500 may include a lower electrode 520, a dielectric layer 530 and an upper electrode 540. The lower electrode 520 may be in contact with the contact pad 510. The lower electrode 520 may include doped polysilicon, a metal silicide, or a metal, and as an example, may be formed in a cylindrical shape. The dielectric layer 530 may be disposed on the lower electrode 520. The dielectric layer 530 may be conformally formed on the insulating layer 410 in the cell area CA. The dielectric layer 530 may be conformally formed on a surface of the lower electrode 520 and the insulating layer 410. The upper electrode 540 may be formed on the dielectric layer 530. The upper electrode 540 may include doped polysilicon, a metal silicide, or a metal.

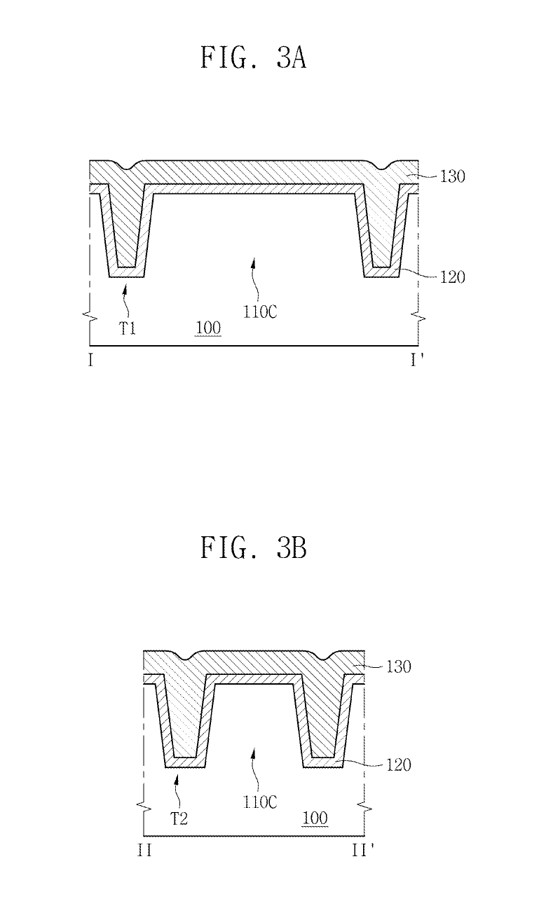

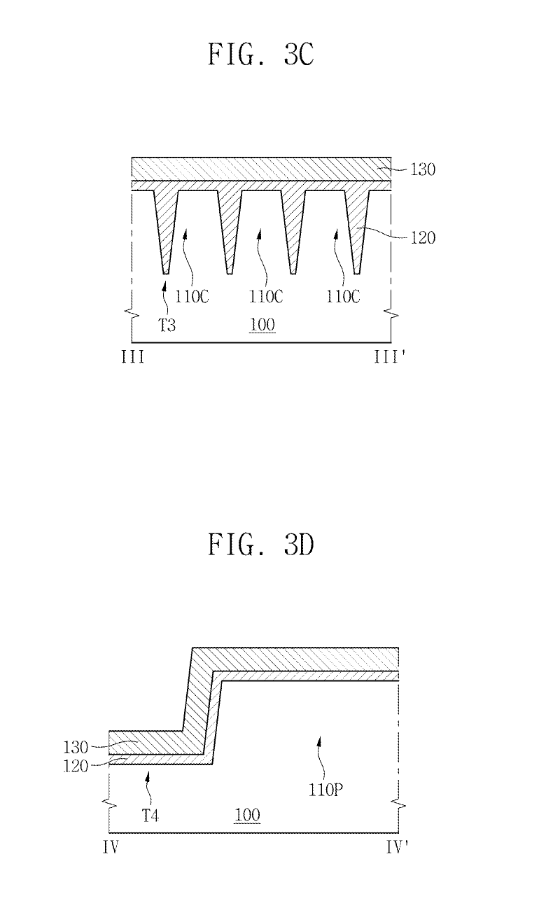

FIGS. 3A to 15D are cross-sectional views showing a method of forming a semiconductor device in accordance with some example embodiments of the inventive concepts.

A method of forming a semiconductor device in accordance with some example embodiments of the inventive concepts will be described with reference to FIGS. 1, 2A to 2C, 3A to 15A, 3B to 15B, 3C to 15C and 3D to 15D. First referring to FIGS. 1, and 3A to 3D, the method of forming a semiconductor device in accordance with some example embodiments of the inventive concepts may include forming an isolating trench T in a substrate 100 including a cell area CA and a peripheral area PA.

Forming the isolating trench T may include forming cell active areas 110C in a cell area CA, and forming peripheral active areas 110P in a peripheral area PA.

The cell active areas 110C and the peripheral active areas 110P may be arranged in an array of island shapes, and may have a bar shape. The substrate 100 may include a silicon wafer, an SOI substrate, an SiGe substrate, an SiC substrate, a compound semiconductor substrate, or various semiconductor substrates. The cell active areas 110C may be arranged to slope with a predetermined (or desired) angle between an X direction and a Y direction as shown in FIG. 1. As an example, the cell active area 110C may be arranged in a Y direction without a slope. The cell active areas 110C and the peripheral active area 110P may be formed with different sizes and arrays. The isolating trench T may be formed to have a predetermined (or desired) width in an isolating area T1 between the cell active areas 110C in a longitudinal direction of the cell active area as shown in FIG. 3A. The isolating trench T may be formed to have a width, similar to the isolating trench of the isolating area T1, in an isolating area T2 between the cell active areas 110C in a Y direction as shown in FIG. 3B. The isolating trench T may be formed to have a width, smaller than the isolating trenches of the isolating areas T1 and T2, in an isolating area T3 between the cell active areas 110C in an X direction as shown in FIG. 3C. The isolating trench T may be formed to have a width, greater than the isolating trenches of the isolating areas T1 and T2, in an isolating area T4 between the cell area CA and the peripheral area PA as shown in FIG. 3D.

A protection layer 120 may be conformally formed on an entire surface of the substrate 100 on which the isolating trench T is formed. The protection layer 120 may be conformally formed on inner walls and bottoms of the isolating trenches T in the isolating areas T1, T2, and T4 as shown in FIGS. 3A, 3B, and 3D. The protection layer 120 may be formed to completely fill the isolating trench T in the isolating area T3 as shown in FIG. 3C. The protection layer 120 may include a silicon oxide layer. The protection layer 120 may be formed by an oxidation process including a thermal oxidation process, a radical oxidation process, and the like, a chemical vapor deposition (CVD) process, or an atomic layer deposition (ALD) process.

A silicon insulating layer 130 may be formed on the protection layer 120. The silicon insulating layer 130 may be a silicon insulating layer having different insulating characteristics from the protection layer 120. As an example, the silicon insulating layer 130 may include a silicon nitride layer.

The silicon insulating layer 130 may be formed to completely fill the isolating trenches T in the isolating areas T1 and T2 as shown in FIGS. 3A and 3B. The silicon insulating layer 130 may be formed on the protection layer 120 filling the isolating trench T in the isolating area T3 as shown in FIG. 3C. The silicon insulating layer 130 may be conformally formed on the protection layer 120 on the inner wall and bottom of the isolating trench T in the isolating area T4 as shown in FIG. 3D.

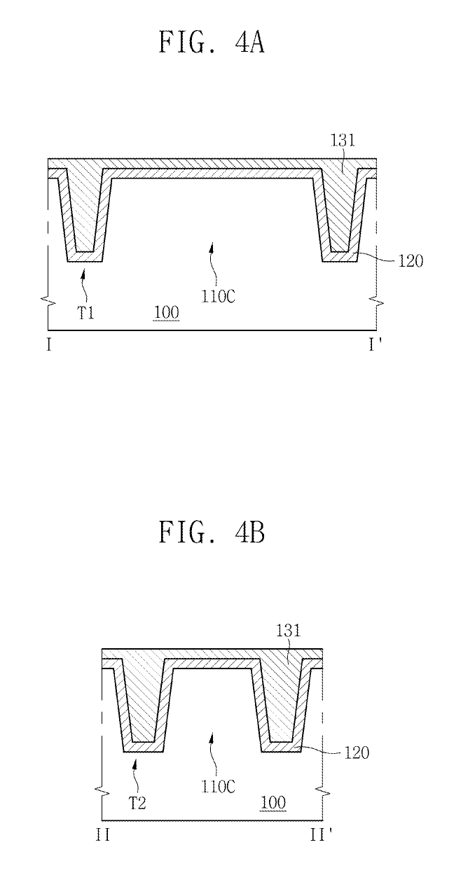

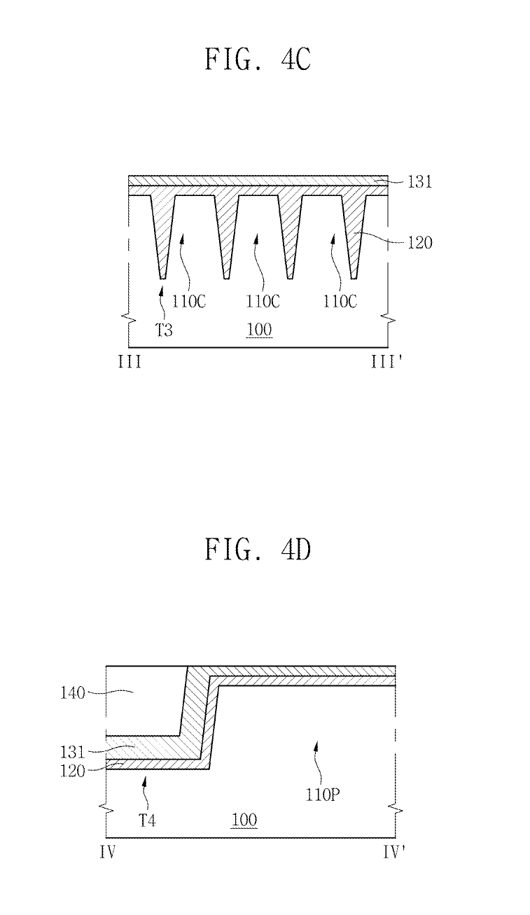

Referring to FIGS. 1, and 4A to 4D, the method of forming a semiconductor device in accordance with some example embodiments of the inventive concepts may include forming a trench insulating layer 140 on the silicon insulating layer 130.

Forming the trench insulating layer 140 may include forming a fluid silicon oxide layer on the silicon insulating layer 130 such as USG, TOSZ, or PE-TEOS. The trench insulating layer 140 may be formed by a flowable CVD (F-CVD) method or a spin coating method.

Forming the trench insulating layer 140 may include forming a protection layer 131 using the silicon insulating layer 130. The protection layer 131 may include planarizing the silicon insulating layer 130 and the trench insulating layer 140. As an example, the protection layer 131 may be formed by simultaneously planarizing the silicon insulating layer 130 and the trench insulating layer 140 using a chemical mechanical polishing (CMP) method. As an example, the protection layer 131 may be formed by an etch-back process of the silicon insulating layer 130, in which an upper surface of the etched trench insulating layer 140 is used as an etch-stop point, after etching an upper surface of the trench insulating layer 140 to have a height of the protection layer 131 to be formed.

The method of forming a semiconductor device in accordance with some example embodiments of the inventive concepts may further include performing an ion implanting process after the protection layer 131 is formed to form a well, a Vt control area, or a source/drain area in the cell area CA. As a result, an impurity area may be formed in the substrate 100 in the cell active area 110C.

The protection layer 120 and the protection layer 131 may be conformally formed on the substrate 100 in the cell active area 110C and the peripheral active area 110P. As shown in FIGS. 4A and 4B, in isolating areas T1 and T2, the protection layer 120 may be conformally formed on the inner wall and the bottom of the isolating trench T, and the protection layer 131 disposed on the protection layer 120 may be formed to fill the isolating trench T. A level of an upper surface of the protection layers 131 formed in the isolating areas T1 and T2 may be same as a level of the upper surface of the protection layer 131 formed in the cell active area 110C. As shown in FIG. 4C, in an isolating area T3, the protection layer 120 may be formed to fill the isolating trench T, and the protection layer 131 may be formed on the protection layer 120. A level of an upper surface of the protection layer 120 in the cell active area 110C may be same as a level of the upper surface of the protection layer 120 in the isolating area T3. A level of the upper surface of the protection layer 131 in the cell active area 110C may be same as a level of the upper surface of the protection layer 131 in the isolating area T3. As shown in FIG. 4D, in isolating area T4, the protection layer 120 may be conformally formed on the inner wall and the bottom of the isolating trench T, the protection layer 131 may be conformally formed on the protection layer 120, and the trench insulating layer 140 may be formed to fill the isolating trench T. The protection layer 131 formed in the isolating area T4 may be formed to have a different thickness from the protection layer 131 formed in the cell active area 110C and the peripheral active area 110P.

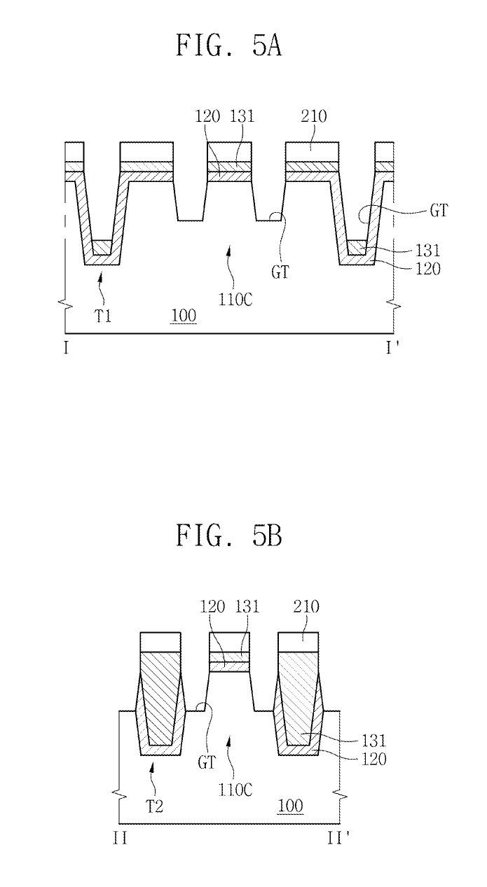

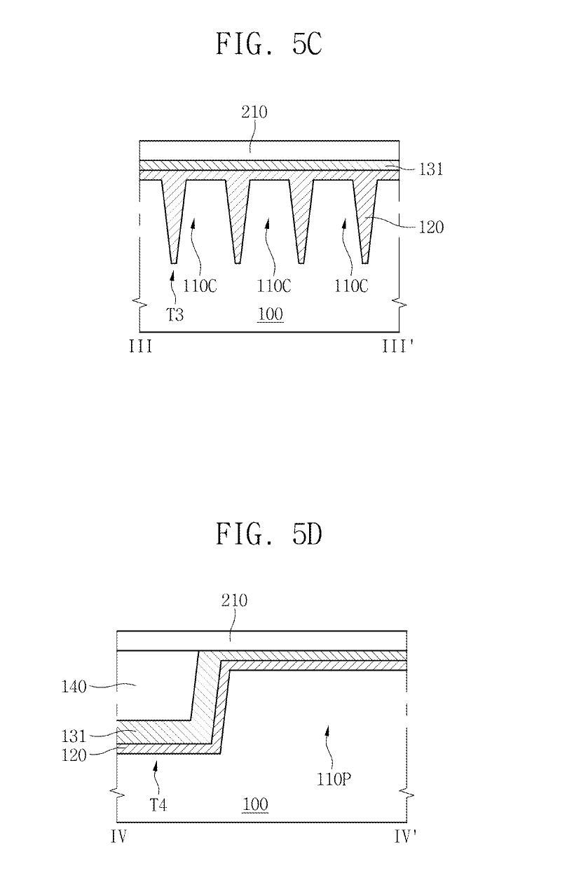

Referring to FIGS. 1, and 5A to 5D, the method of forming a semiconductor device in accordance with some example embodiments of the inventive concepts may include forming gate trenches GT in the substrate 100.

Forming the gate trenches GT may include forming a mask layer on the protection layer 131, forming a hard mask 210 by patterning the mask layer in an X direction, and forming gate trenches GT by etching the protection layer 131, the protection layer 120 and the substrate 100 using the hard mask 210. The hard mask 210 may be a line shape crossing the cell active areas 110C and the isolating trench T such as the word line 200 shown in FIG. 1.

The mask layer may be formed by a single or multi-layer thin layer including a material having a greater etch selectivity with respect to the protection layer 120, the protection layer 131 and the substrate 100. As an example, the mask layer may be formed by a stacked structure of a silicon oxide layer and a poly hard mask, a stacked structure of a silicon oxide layer and a chrome hard mask, or SiOC.

At least two gate trenches GT may be formed in one cell active area 110C. As an example, when the cell active area 110C is formed in a diagonal line shape in a Y direction, the gate trenches GT may be formed to cross the cell active area 110C in a diagonal line direction. As an example, when the cell active area 110C is formed in a Y direction, the gate trenches GT may be formed to cross perpendicular to the cell active area 110C. The gate trenches GT may be formed in the cell active area 110C to expose the substrate 100, and formed to expose the protection layer 120 on the inner wall and the protection layer 131 on the bottom in the isolating area T1 as shown in FIG. 5A. A level of a bottom surface of the gate trenches GT in the isolating area T1 may be lower than a level of a bottom surface of the gate trenches GT in the cell active area 110C, due to different etch rates between the substrate 100 and the protection layer 131. The gate trenches GT may be formed to expose the substrate 100 at the bottom and one inner wall thereof in the cell active area 110C, and side surfaces of an upper portion of the protection layer 131 in the isolating area T2 as shown in FIG. 5B. The gate trenches GT may be formed to expose the protection layer 120 in the isolating area T2 as shown in FIG. 5B.

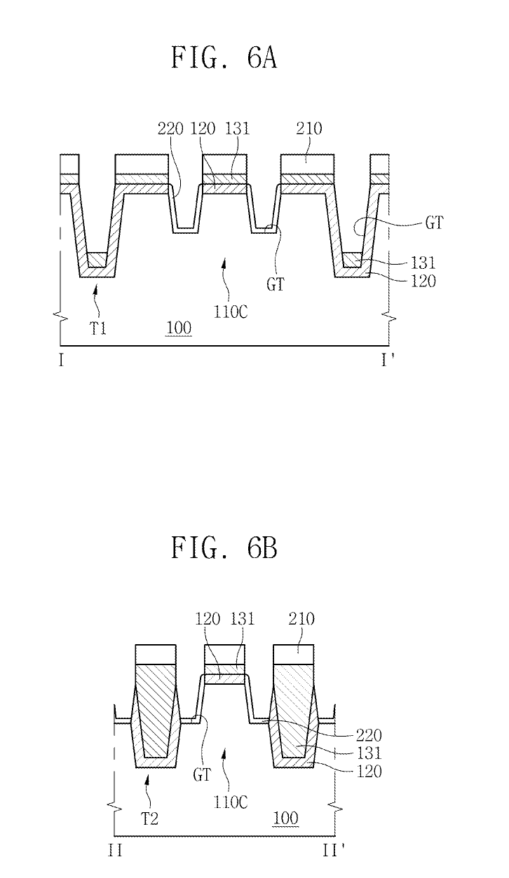

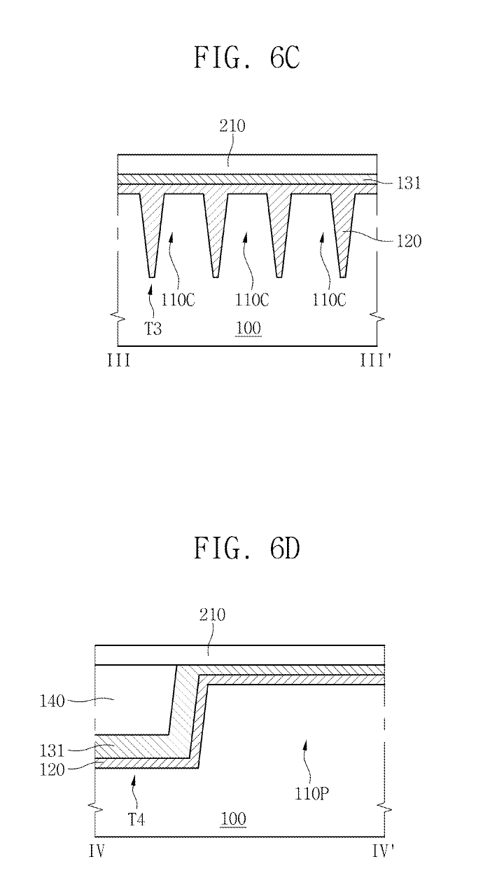

Referring to FIGS. 1 and 6A to 6D, the method of forming a semiconductor device in accordance with some example embodiments of the inventive concepts may include forming cell gate insulating layers 220 on the substrate 100.

Forming the cell gate insulating layers 220 may include performing an oxidation process such as a thermal oxidation process or a radical oxidation process. The cell gate insulating layers 220 may include a silicon oxide layer. The cell gate insulating layers 220 may be formed only on the substrate 100 exposed on the inner wall of the gate trenches GT in the cell active area 110C by the oxidation process.

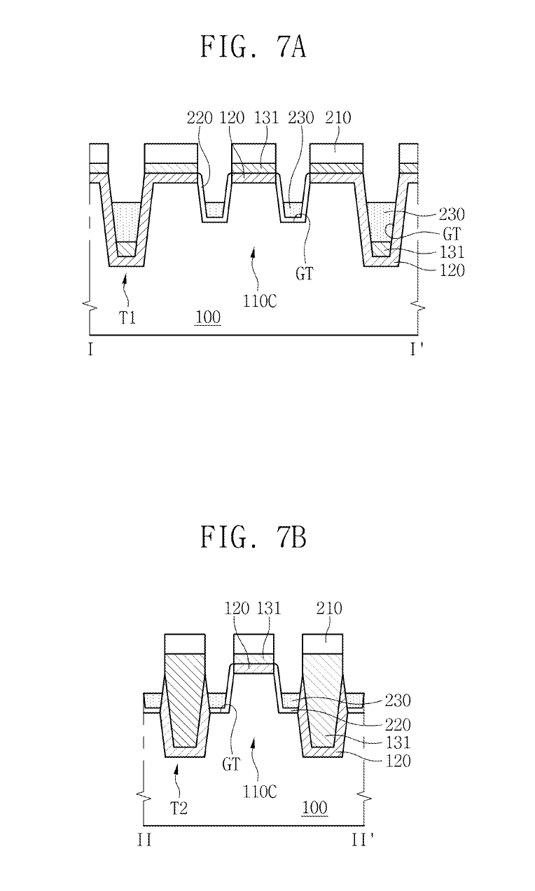

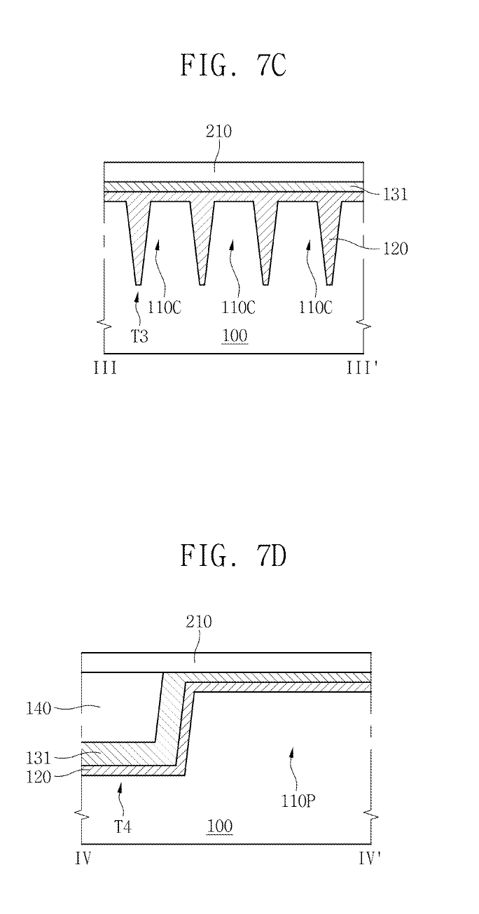

Referring to FIGS. 1, and 7A to 7D, the method of forming a semiconductor device in accordance with some example embodiments of the inventive concepts may include forming cell gate lines 230 in the gate trenches GT.

The cell gate lines 230 may be formed to fill the lower area of the gate trenches GT. A level of upper surfaces of the cell gate lines 230 may be lower than a level of the upper surface of the substrate 100 in the cell active area 110C. A level of the upper surfaces of the cell gate lines 230 in the cell active area 110C may be same as a level of the upper surfaces of cell gate lines 230 in the isolating area T1. The cell gate line 230 may be formed on the cell gate insulating layer 220 in the cell active area 110C as shown in FIG. 7A or 7B. The cell gate line 230 may be formed on the protection layer 131 in the isolating area T1 as shown in FIG. 7A. The cell gate lines 230 may be a conductive thin layers including one of a metal, a metal silicide or a doped poly-silicon. As an example, forming the cell gate lines 230 may include depositing a metal layer such as tungsten on the entire surface of the substrate 100 to fill the gate trenches GT, and bring down a level of an upper surface of the metal layer so that the level of the upper surface of the metal layer in the gate trenches GT is lower than a level of the upper surface of the substrate 100. As an example, bring down the level of the upper surface of the metal layer may include performing an etch-back process. The metal layer disposed on the hard mask 210 may be removed by the etch-back process. As an example, bring down the level of the upper surface of the metal layer may be performed after removing the metal layer on the hard mask 210 using a CMP method.

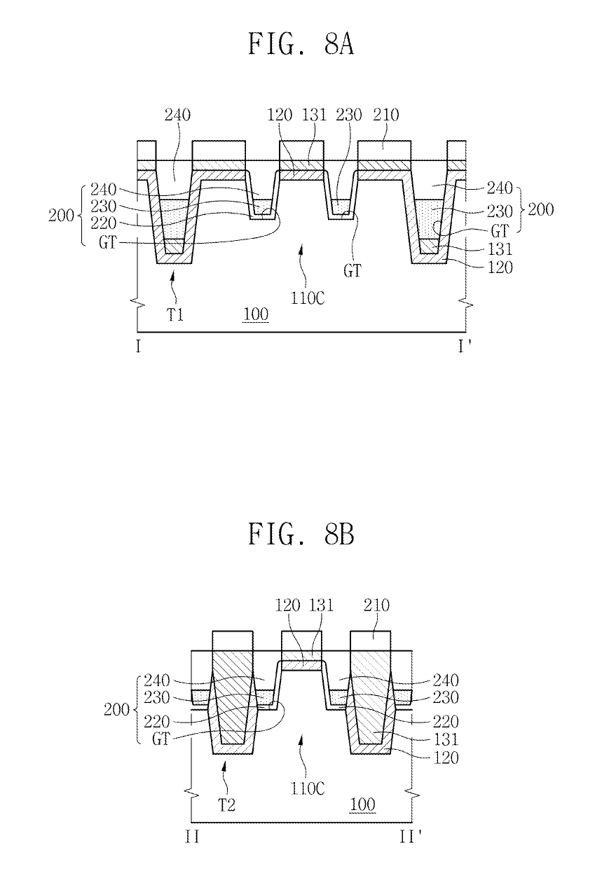

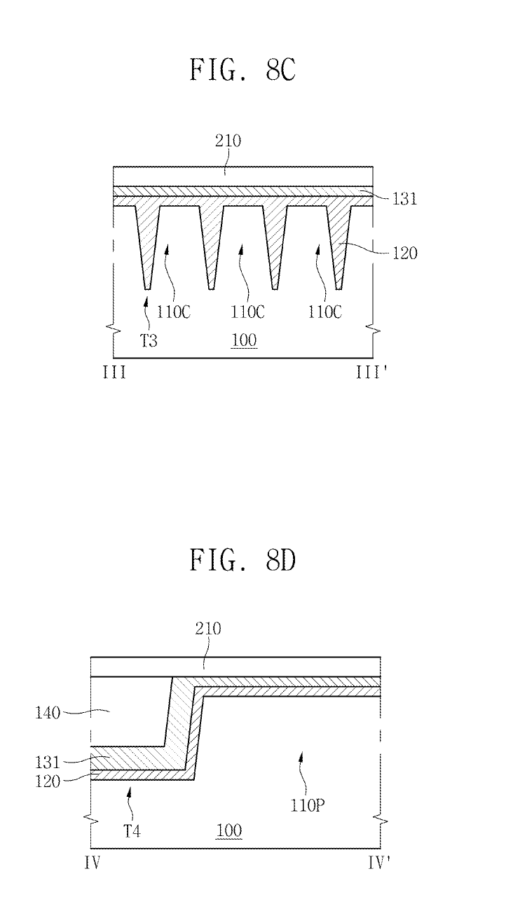

Referring to FIGS. 1, and 8A to 8D, the method of forming a semiconductor device in accordance with some example embodiments of the inventive concepts may include forming cell gate structures 200.

Forming the cell gate structures 200 may include forming gate capping layers 240 on the cell gate lines 230 to completely fill the gate trenches GT. Each of the cell gate structures 200 may include the gate trench GT, the cell gate insulating layer 220, the cell gate line 230, and the gate capping layer 240. A level of upper surfaces of the gate capping layers 240 may be same as the level of the upper surface of the protection layer 131 in the cell active area 110C. The gate capping layers 240 may be a silicon oxide layer having an etch rate the same as or similar to the protection layer 131. As an example, the gate capping layers 240 may be a silicon nitride layer or a silicon oxynitride layer. As an example, forming the gate capping layers 240 may include depositing a silicon nitride layers on the entire surface of the substrate 100 to fill the gate trenches GT, and bring down a level of an upper surface of the silicon nitride layer in the gate trenches GT so that the level of the upper surface of the silicon nitride layer in the gate trenches GT is same as a level of the upper surface of the protection layer 131 in the cell active area 110C. As an example, bring down the level of the upper surface of the silicon nitride layer may include an etch-back process. The silicon nitride layer disposed on the hard mask 210 may be removed by the etch-back process. As an example, bring down the level of the upper surface of the silicon nitride layer may be performed after removing the silicon nitride layer on the hard mask 210 using a CMP method.

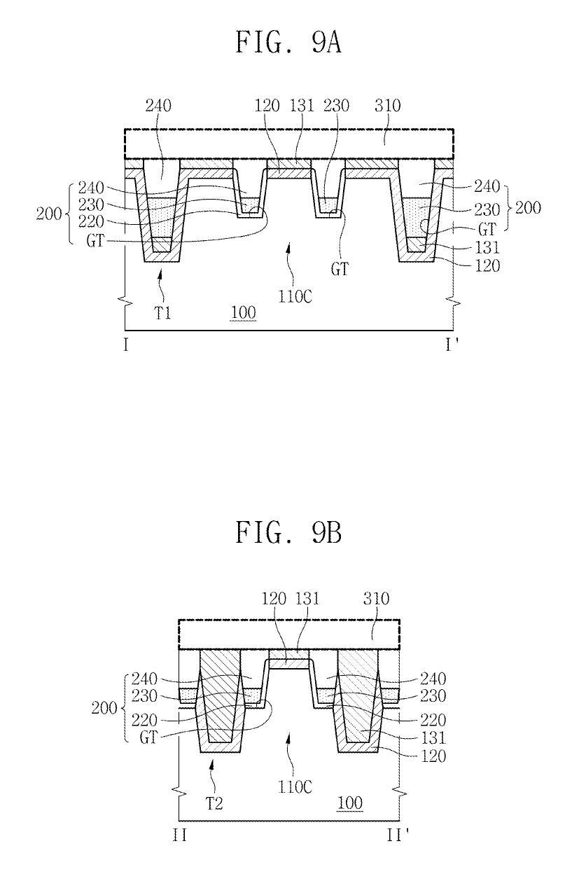

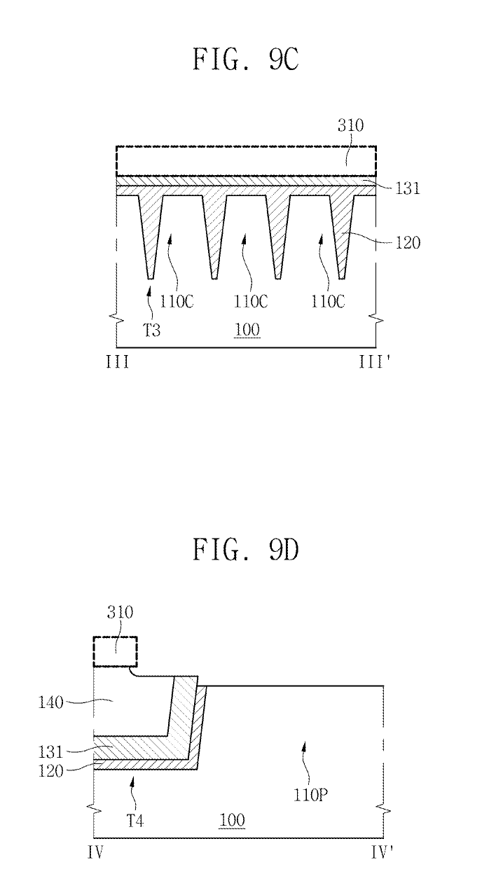

Referring to FIGS. 1, and 9A to 9D, the method of forming a semiconductor device in accordance with some example embodiments of the inventive concepts may include removing the hard mask 210, forming a masking layer 310 on the cell area CA of the substrate 100, and removing the protection layer 131 and the protection layer 120 on the peripheral area PA using the masking layer 310.

The masking layer 310 may be formed on a part of the isolating area T4 as shown in FIG. 9D. The substrate 100 may be not covered by the masking layer 310 in the peripheral active area 110P. The protection layer 131 on the peripheral active area 110P may be exposed by the masking layer 310. The masking layer 310 may be a photoresist layer.

Removing the protection layer 131 and the protection layer 120 using the masking layer 310 may include exposing the substrate 100 in the peripheral active area 110P, as shown in FIG. 9D. Removing the protection layer 131 and the protection layer 120 may etching the protection layer 131 and the protection layer 120 using the masking layer 310. As an example, the protection layer 131 formed in the peripheral area PA may be removed by a dry etching process, and then the exposed protection layer 120 may be removed by a wet etching process. In the isolating area T4 as shown in FIG. 9D, a higher level of the protection layer 120 may be lower than a higher level of the protection layer 131, and a level of a portion of the trench insulating layer 140 covered by the masking layer 310 may be higher than a level of a portion of the trench insulating layer 140 exposed by the masking layer 310. An upper surface of the trench insulating layer 140 may have a step in the peripheral area PA of the substrate 100 by an etching process.

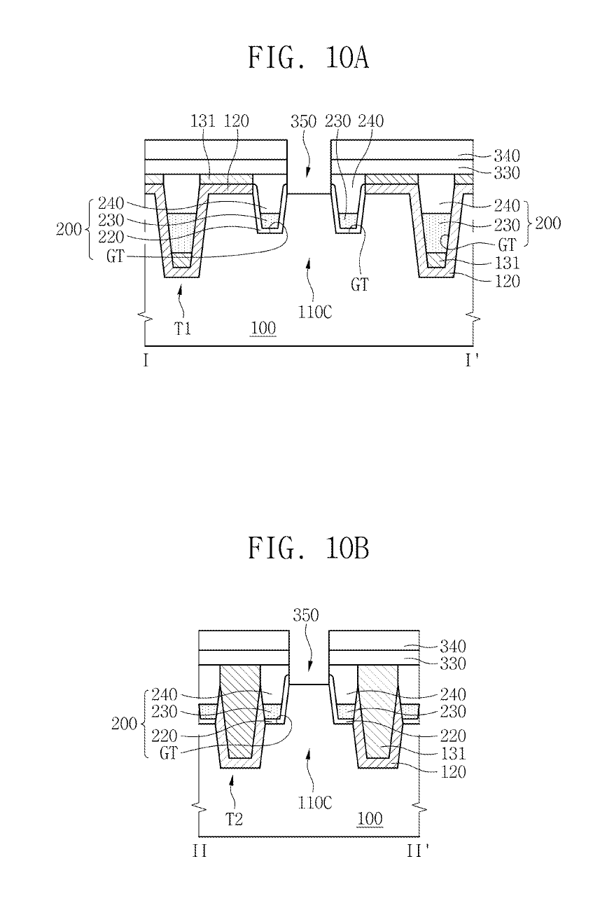

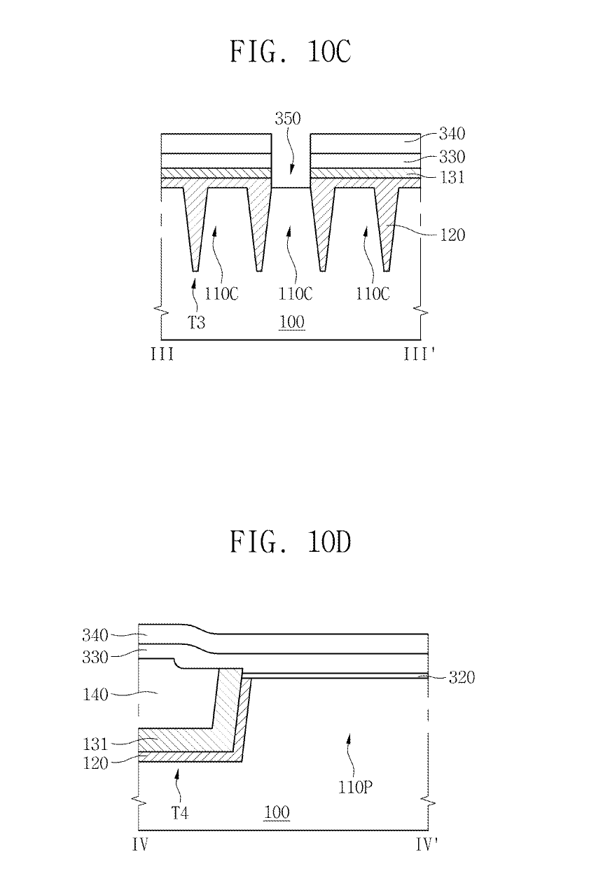

Referring to FIGS. 1, and 10A to 10D, the method of forming a semiconductor device in accordance with some example embodiments of the inventive concepts may include removing the masking layer 310, forming a peripheral gate insulating layer 320 on the peripheral active area 110P the substrate 100, forming a conductive layer 330 on the substrate 100, forming a hard mask 340 on the conductive layer 330, and forming bit line contact hole 350 exposing cell active area 110C.

Forming a peripheral gate insulating layer 320 may include performing an oxidation process on the substrate 100. The oxidation process may include a thermal oxidation process or a radical oxidation process. The peripheral gate insulating layer 320 may be not formed in the cell area CA since the protection layer 131 and the gate capping layer 240 are formed on the cell area CA of the substrate 100 as shown in FIGS. 10A to 10C. The peripheral gate insulating layer 320 may be formed only on the peripheral active area 110P of the substrate 100.

The conductive layer 330 may be formed on an entire surface of the substrate 100. The conductive layer 330 may be formed on the peripheral gate insulating layer 320. The conductive layer 330 may be formed on the protection layer 131 and the gate capping layer 240 on the substrate 100 in the cell active area 110C. The conductive layer 330 may include doped polysilicon, a metal silicide, or a metal.

The bit line contact hole 350 may penetrate the hard mask 340, the conductive layer 330, the protection layer 131, and the protection layer 120. The bit line contact hole 350 may exposed the cell active area 110C located between the gate trenches GT. The cell active area 110C of the substrate 100 exposed by the bit line contact hole 350 may be recessed due to forming the bit line contact hole 350.

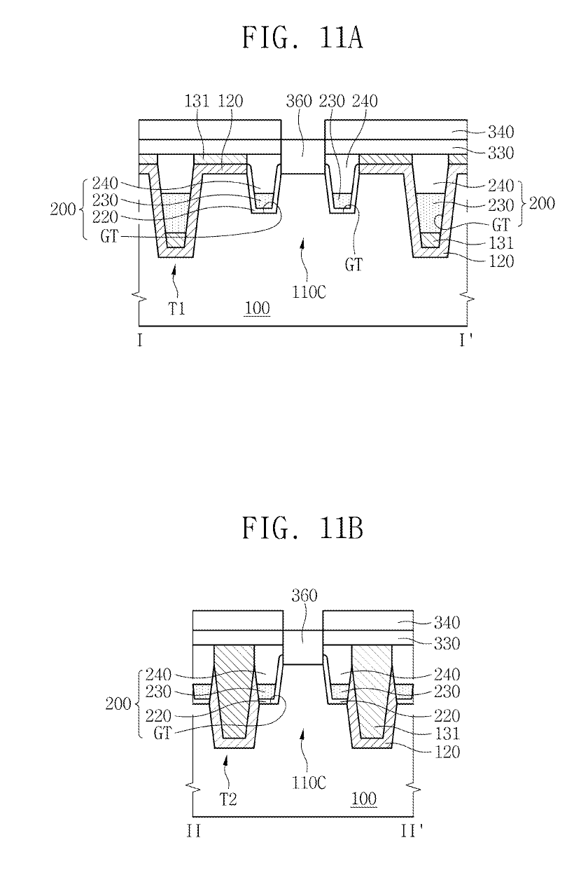

Referring to FIGS. 1, and 11A to 11D, the method of forming a semiconductor device in accordance with some example embodiments of the inventive concepts may include forming a bit line contact plug 360 inside the bit line contact hole 350.

The bit line contact plug 360 may include single-crystalline silicon grown by an epitaxial method, doped polysilicon, a metal silicide, or a metal. As an example, a level of an upper surface of the bit line contact plug 360 may be same as a level of an upper surface of the conductive layer 330. As an example, the level of the upper surface of the bit line contact plug 360 may be lower than the level of the upper surface of the conductive layer 330. As an example, forming the bit line contact plug 360 may include growing single-crystalline silicon on the upper surface of the substrate 100 exposed by the bit line contact hole 350 using an epitaxial method. As an example, forming the bit line contact plug 360 may include depositing a conductive material such as doped polysilicon, a metal silicide, or a metal on the hard mask 340 to completely fill the bit line contact hole 350, and bring down a level of an upper surface of the conductive material by an etch-back process. Bring down the level of the upper surface of the conductive material may include removing the conductive material disposed on the hard mask 340 using a CMP method, and performing etch-back process of the conductive material retained inside the bit line contact hole 350.

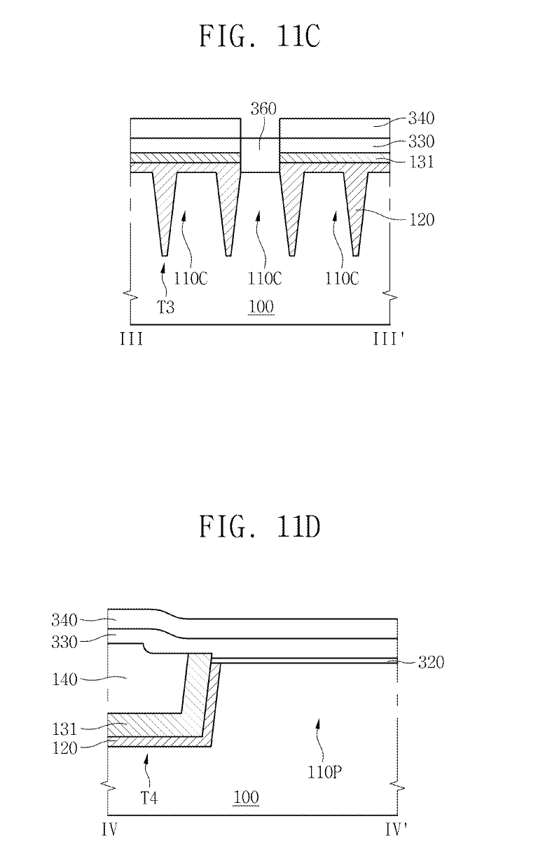

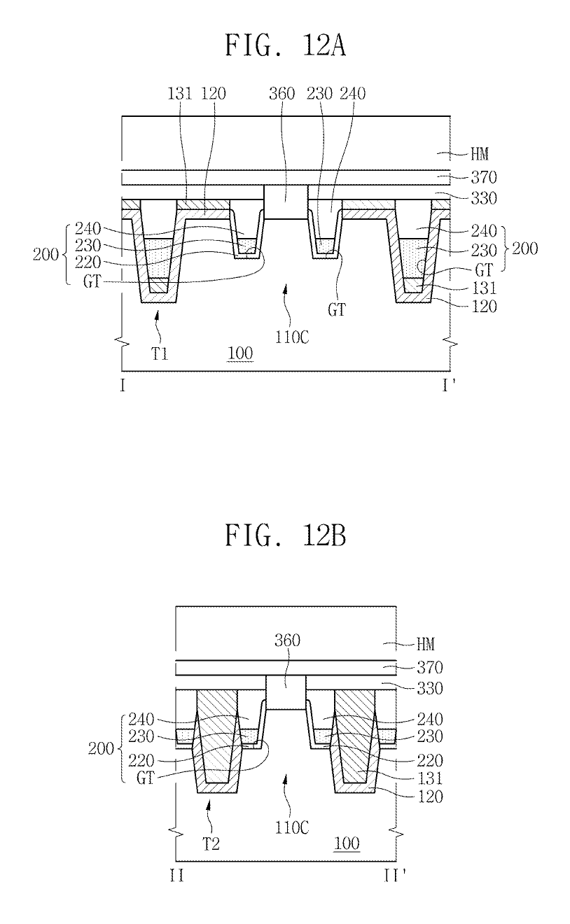

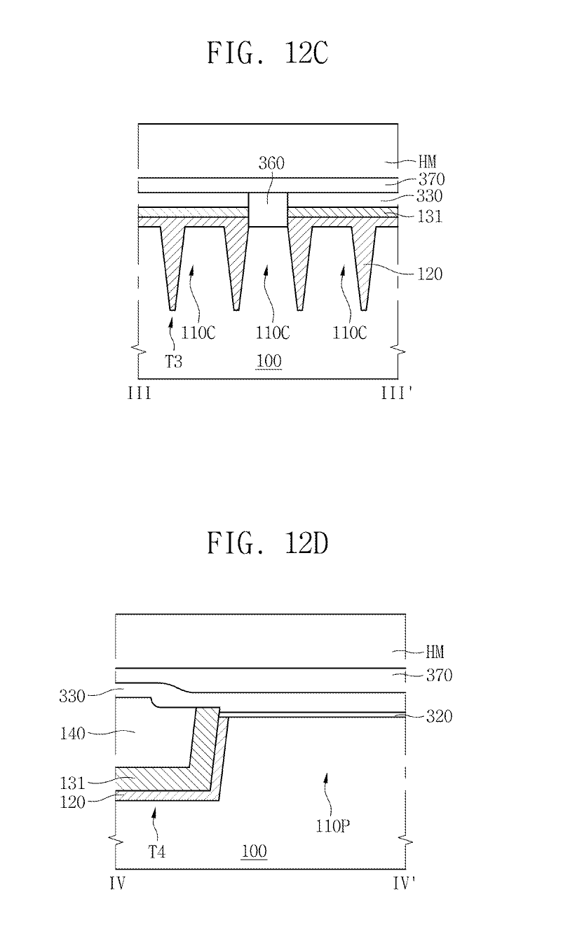

Referring to FIGS. 1, and 12A to 12D, the method of forming a semiconductor device in accordance with some example embodiments of the inventive concepts may include removing the hard mask 340, forming a conductive layer 370 on the conductive layer 330 and the bit line contact plug 360, and forming a hard mask HM on the conductive layer 370.

The conductive layer 370 may include doped polysilicon, a metal silicide, or a metal. The hard mask HM may include a silicon insulating layer such as a silicon nitride layer.

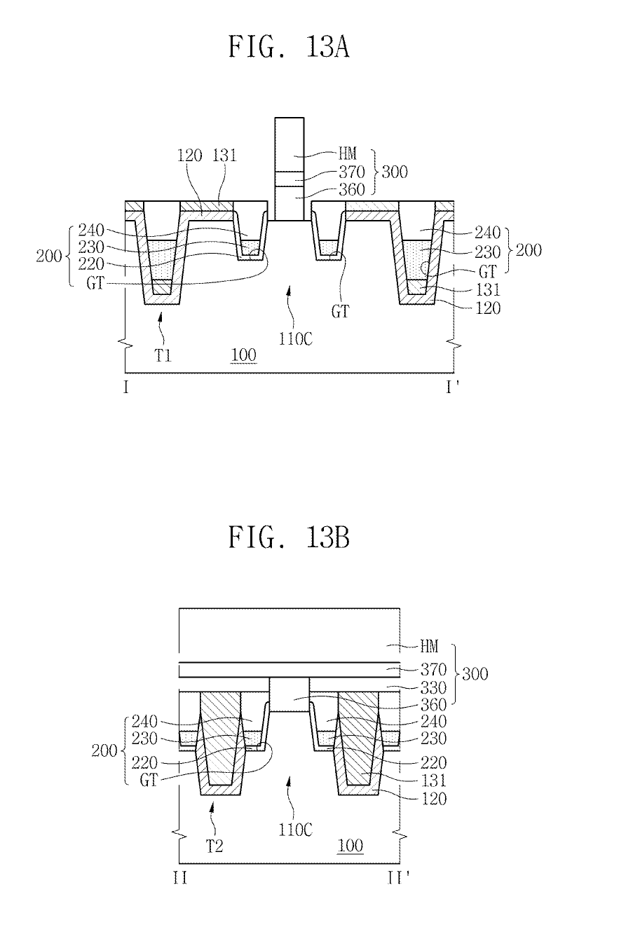

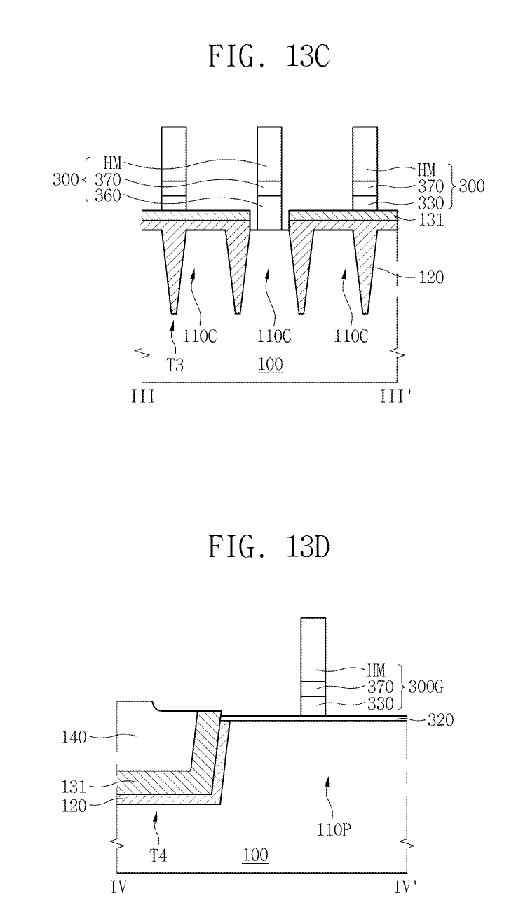

Referring to FIGS. 1, and 13A to 13D, the method of forming a semiconductor device in accordance with some example embodiments of the inventive concepts may include forming bit line structures 300 in the cell area CA, and a peripheral gate line structure 300G in the peripheral area PA.

Forming the bit line structures 300 and the peripheral gate line 300G may include forming a mask pattern on the hard mask HM and patterning the hard mask HM, the conductive layer 370, the conductive layer 330 and the bit line contact plug 360 using the mask pattern. The mask pattern may be a line shape. The mask pattern may cross the cell active areas 110C, the peripheral active area 110P and the isolating trench T. The mask pattern may extend in the Y direction. As an example, an expanded direction of the mask pattern in the peripheral area PA may be different from an expanded direction of the mask pattern in the cell area CA. A direction of the peripheral gate line structure 300G may be different from a direction of the bit line structure 300.

Each of the bit line structures 300 may be arranged substantially perpendicular to the cell gate structures 200. Each of the bit line structures 300 may include the conductive layer 330, the bit line contact plug 360, the conductive layer 370, and the hard mask HM in the cell area CA.

The peripheral gate line structure 300G may include the conductive layer 330, the conductive layer 370, and the hard mask HM on the peripheral gate insulating layer 320 in the peripheral area PA.

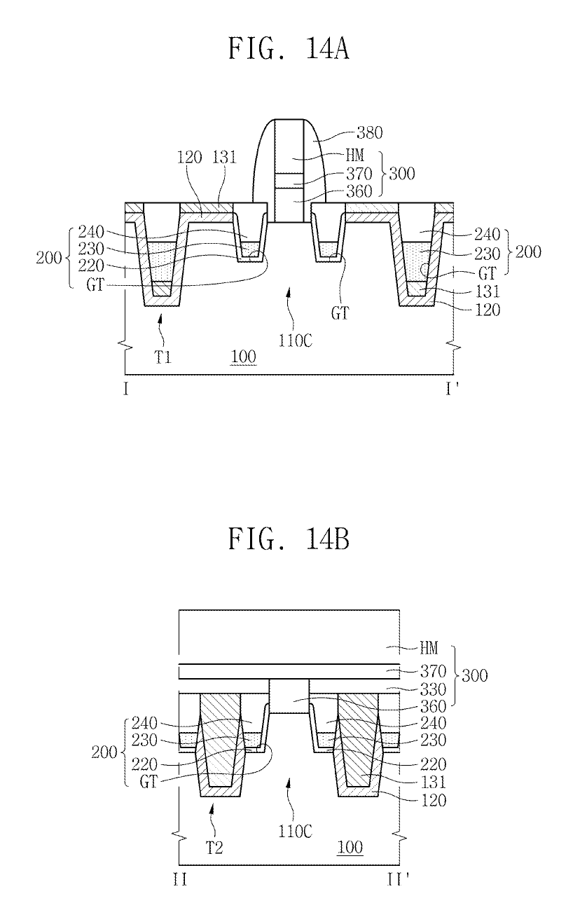

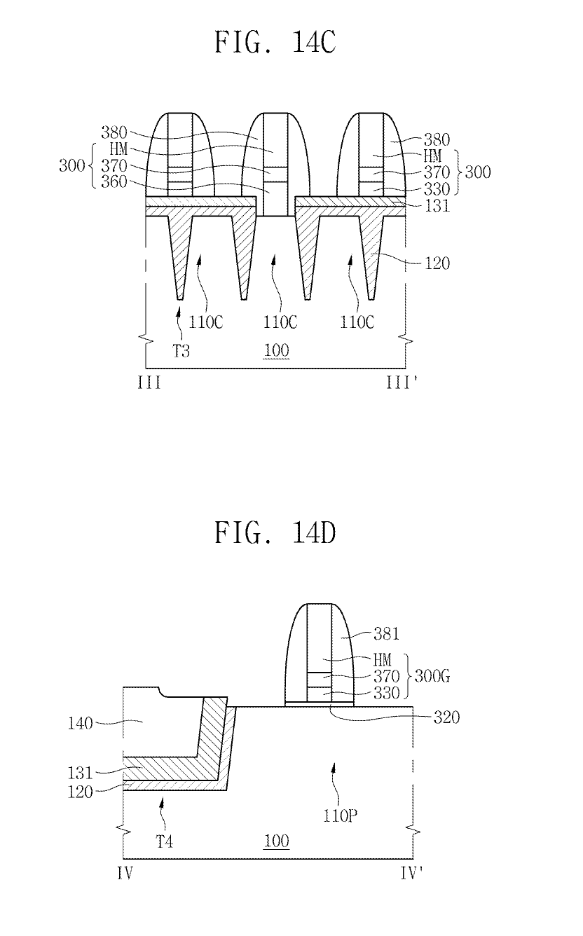

Referring to FIGS. 1, and 14A to 14D, the method of forming a semiconductor device in accordance with some example embodiments of the inventive concepts may include forming spacers 380 on side walls of the bit line structures 300, and spacers 381 on a side walls of the peripheral gate line structure 300G.

The spacers 380 and 381 may be a silicon insulating layer such as a silicon oxide layer, a silicon nitride layer, or a multi-layer structure of a silicon oxide layer and a silicon nitride layer.

A portion of the peripheral gate insulating layer 320 disposed outside the spacers 381 may be removed by forming the spacers 381. Side surfaces of the peripheral gate insulating layer 320 may be vertically align with the side surfaces of the spacers 381. As an example, impurity areas may be formed in the substrate 100 exposed by the spacers 381 and the peripheral gate line structure 300G in the peripheral active area 110P. The impurity areas may be formed by doping impurity into the substrate 100 in the peripheral area PA using an ion implanting process.

Referring to FIGS. 1 and 15A to 15D, the method of forming a semiconductor device in accordance with some example embodiments of the inventive concepts may include forming an insulating layer 410 on the entire surface of the substrate 100, forming storage contacts BC on the cell active area 110C and forming source/drain contacts 420 on the peripheral active area 110P.

The insulating layer 410 may include, for example, a silicon oxide layer, a silicon oxynitride layer, or a silicon nitride layer. A level of an upper surface of the insulating layer 410 may be same as a level of an upper surface of the hard mask HM. Forming the insulating layer 410 may include planarizing the insulating layer 410 by the planarization process.

The storage contacts BC may be connected to the cell active areas 110C. The storage contacts BC may be spaced from the bit line contact plug 360. The storage contacts BC may be spaced from the gate trenches GT. The storage contacts BC may penetrate the insulating layer 410 in the cell area CA. The source/drain contacts 420 may be connected to the peripheral active area 110P. The source/drain contacts 420 may penetrate the insulating layer 420 in the peripheral area PA.

As an example, forming storage contacts BC and source/drain contacts 420 may include forming a mask pattern on the insulating layer 410, forming contact holes penetrating the insulating layer 410, the protection layer 131 and the protection layer 120 by etching process using the mask pattern, and filling the contacts holes with a conductive material. As an example, forming the mask pattern may include forming a mask layer on the insulating layer 410 and removing a portion of the mask layer corresponding the cell active area 110C outside the gate trench GT and the bit line contact plug 360, and the peripheral active area 110P outside the peripheral gate line structure 300G and the spacers 381. The substrate 100 under the contact hole may be recessed due to over-etching. The storage contact BC may be formed to partially overlap the isolating area T3 as shown in FIGS. 1 and 15C.

Referring to FIGS. 1, and 2A to 2D, the method of forming a semiconductor device in accordance with some example embodiments of the inventive concepts may include forming the contact pads 510 and contact pads 511 connected to on the insulating layer 410, and forming information storage elements 500 on the contact pads 510.

The contact pads 510 may be connected to the storage contacts BC. The contact pads 510 may be connected to the source/drain contacts 420. Forming the contact pads 510 and contact pads 511 may include forming a conductive layer on the insulating layer 410, and patterning the conductive layer.

The information storage elements 500 may be formed on the insulating layer 410 of the cell area CA. The information storage elements 500 may include a capacitor. Each of the information storage elements 500 may include a lower electrode 520, a dielectric layer 530, and an upper electrode 540.

The lower electrode 520 may be connected to corresponding contact pad 510 in the cell area CA. The lower electrode 520 may be formed by forming a conductive layer on the insulating layer 410, the contact pads 510 and the contact pads 511, and patterning the conductive layer. The lower electrode 520 may include doped polysilicon, a metal silicide, or a metal.

The dielectric layer 530 may be formed on the lower electrodes 520. The dielectric layer 530 may be conformally formed on a surface of the lower electrode 520, an upper area of the hard mask HM, and insulating layer 410.

The upper electrode 540 may be formed on the dielectric layer 530. The dielectric layer 530 and the upper electrode 540 may be formed at same time. As an example, the dielectric layer 530 and the upper electrode 540 may be formed by forming a dielectric film on the insulating layer 410, forming a conductive layer on the dielectric film, and removing the dielectric film and the conductive layer on the peripheral area PA. The upper electrode 540 may include, for example, doped polysilicon, a metal silicide, or a metal.

A method of forming the semiconductor device in accordance with some example embodiments of the inventive concepts may use a silicon insulating layer filling an isolating trench as a protection layer without forming an extra thin layer to protect a cell area, and thus, a process is simple. The method may prevent a stringer caused by a metal thin layer formed in a boundary area between the cell area and the peripheral area, and thus, operational reliability of the semiconductor device may be improved.

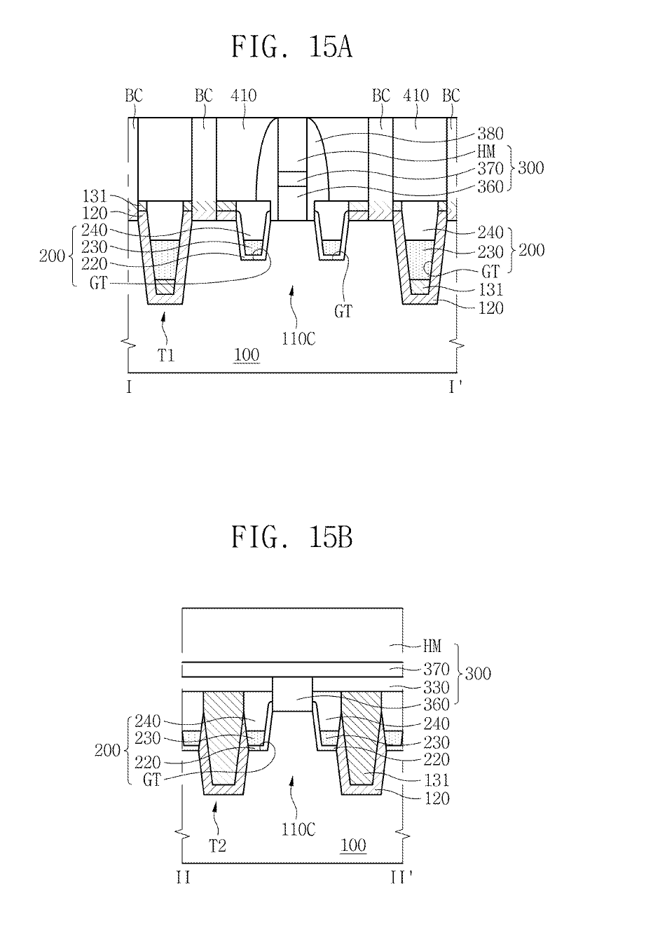

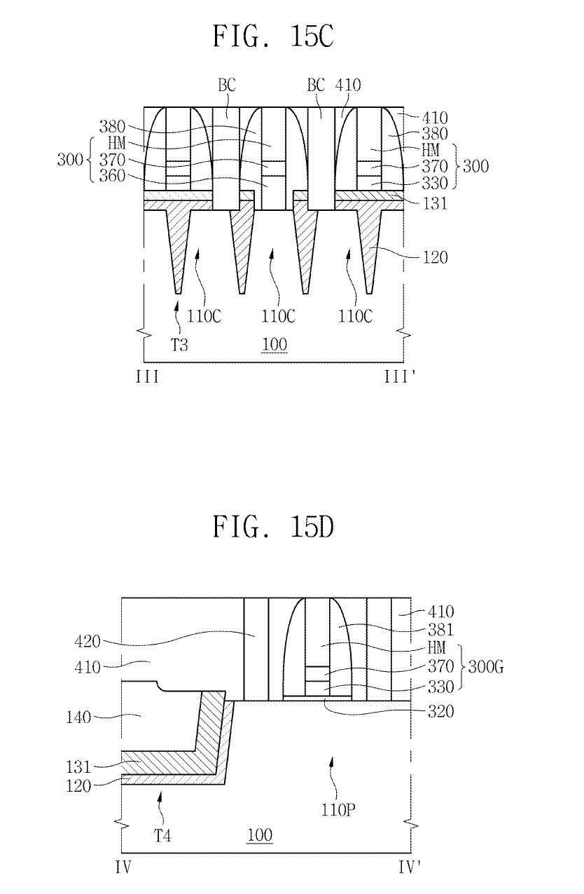

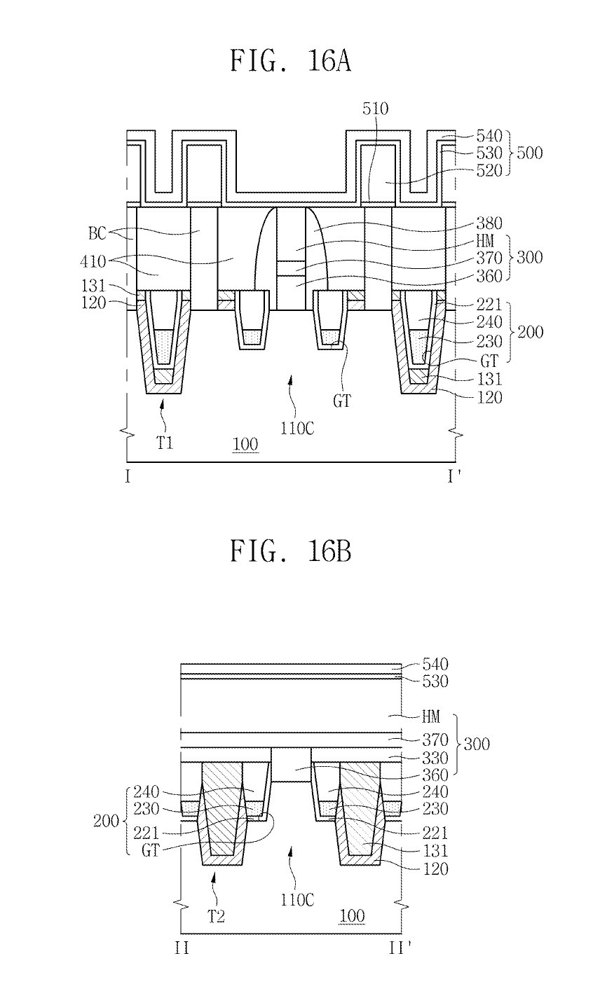

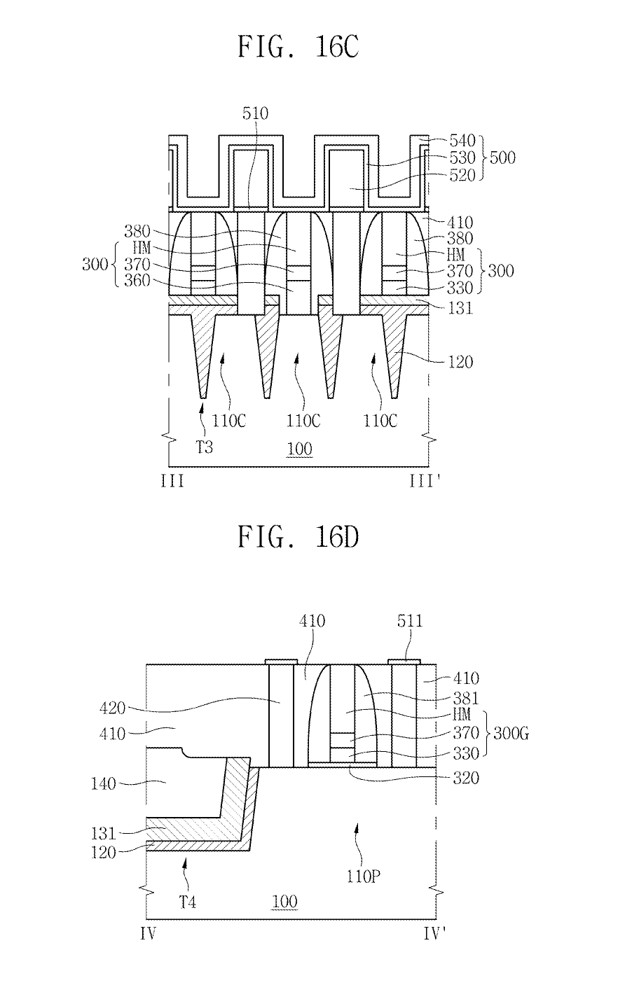

FIGS. 16A to 16D are cross-sectional views showing a semiconductor device.

Referring to 16A to 16D, the semiconductor device in accordance with some example embodiments of the inventive concepts may include a cell gate insulating layer 221 conformally formed on an inner wall and bottom of a gate trench GT, a cell gate line 230 filling a lower portion of the gate trench GT, and a gate capping layer 240 configured to fill an upper portion of the gate trench GT.

The cell gate insulating layer 221 may include a silicon oxide layer or a metal oxide layer. The cell gate insulating layer 221 may be formed by, for example, a CVD or ALD process. A level of an upper surface of the cell gate insulating layer 221 formed on the inner wall of the gate trench GT may be same as a level of the upper surface of the protection layer 131 formed in the cell active area 110C. A level of an upper surface of the cell gate line 230 may be lower than a level of the upper surface of the substrate 100 in the cell active area 110C. A level of the upper surface of the cell gate line 230 in the cell active area 110C may be same as a level of the upper surface of the cell gate line 230 in an isolating area T1. The cell gate line 230 may include a metal, a metal silicide, or a conductive thin layer such as doped poly-silicon. The cell gate line 230 may be formed on the cell gate insulating layer 221 in the cell active area 110C and the isolating area T1 as shown in FIG. 16A. A level of an upper surface of the gate capping layer 240 may be same as a level of the upper surface of the protection layer 131 in the cell active area 110C.

Other components of the semiconductor device in accordance with some example embodiments of the inventive concepts will be understood with reference to FIGS. 2A to 2D.

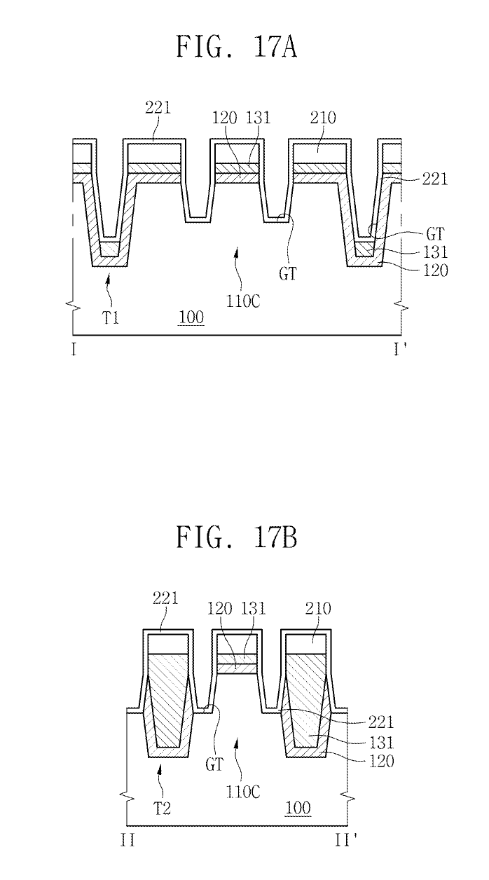

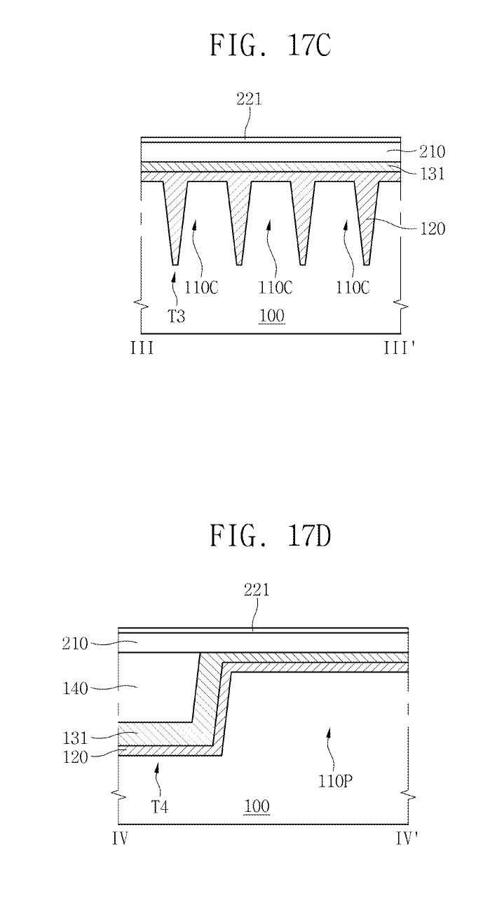

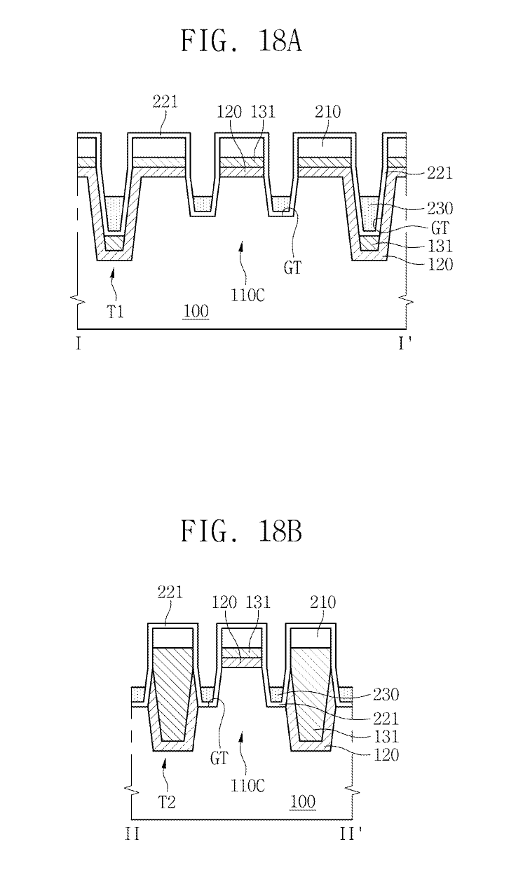

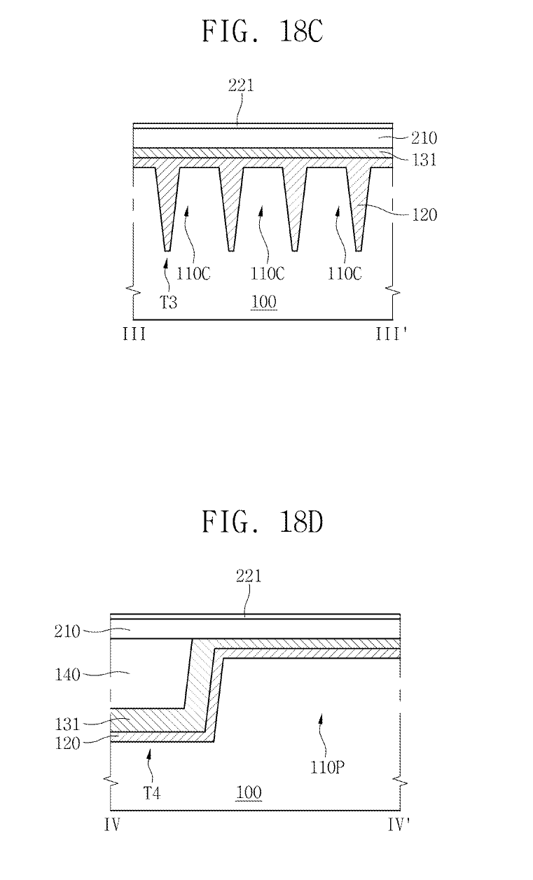

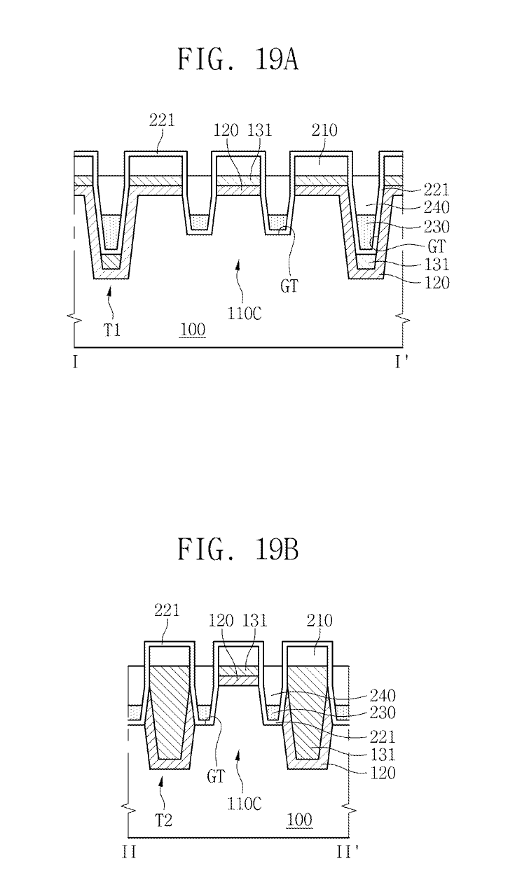

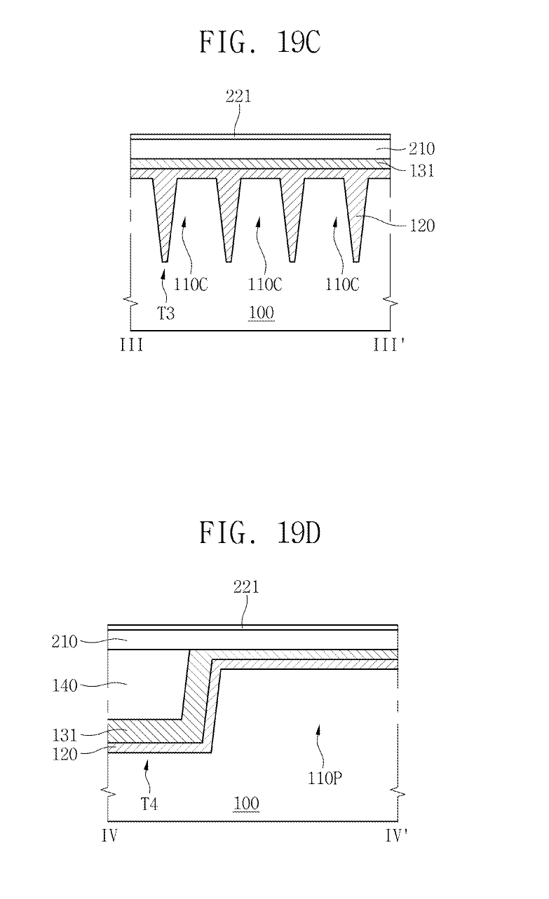

FIGS. 17A to 20A, 17B to 20B, 17C to 20C and 17D to 20D are views showing a method of forming a semiconductor device in accordance with embodiment of the inventive concept.

A method of forming a semiconductor device in accordance with some example embodiments of the inventive concepts will be described with reference to FIGS. 17A to 20A, 17B to 20B, 17C to 20C and 17D to 20D. First referring to 17A to 17D, the method of forming a semiconductor device in accordance with some example embodiments of the inventive concepts may include conformally forming a cell gate insulating layer 221 on an entire surface of the substrate 100 including gate trenches GT.

The cell gate insulating layer 221 may be formed by, for example, a CVD process or an ALD process. The cell gate insulating layer 221 may include a silicon oxide layer or a metal oxide layer.

Referring to 18A to 18D, the method of forming a semiconductor device in accordance with some example embodiments of the inventive concepts may include forming a cell gate line 230 in the gate trenches GT.

The cell gate line 230 may fill the lower portion of the gate trenches GT. A level of an upper surface of the cell gate line 230 may be lower than a level of the upper surface of the substrate 100 in the cell active area 110C. The level of the upper surface of the cell gate line 230 in the cell active area 110C may be same as the level of the upper surface of the cell gate line 230 in the isolating area T1. The cell gate line 230 may be formed on the cell gate insulating layer 221 inside gate trench GT. The cell gate line 230 may include a metal, a metal silicide, or a conductive thin layer such as doped poly-silicon. As an example, the gate trench GT may be formed by depositing a metal layer such as tungsten layer on an entire surface of the substrate 100 to fill the gate trenches GT, and bring down a level of an upper surface of the metal layer using an etch-back process. The metal layer on the hard mask 210 may be removed by the etch-back process. As an example, the metal layer on the hard mask 210 may be removed before the etch-back process using a CMP method.

Referring to 19A to 19D, the method of forming a semiconductor device in accordance with some example embodiments of the inventive concept may include forming a gate capping layer 240 on the cell gate line 230.

The gate capping layer 240 may be completely filled the gate trench GT. Cell gate structures 200 may be formed by forming the gate capping layer 240. Each of the cell gate structures 200 may include the gate trench GT, the cell gate insulating layer 221, the cell gate line 230, and the gate capping layer 240. A level of an upper surface of the gate capping layer 240 may be same as a level of the upper surface of the protection layer 131 formed in the cell active area 110C. The gate capping layer 240 may be formed by a silicon oxide layer having an etch rate the same as or similar to the protection layer 131. The gate capping layer 240 may include a silicon nitride layer or a silicon oxynitride layer. As an example, forming the gate capping layer 240 may include depositing a silicon nitride layer on an entire surface of the substrate 100 to completely fill the gate trenches GT, and performing the etch-back process of the silicon nitride layer so that a level of an upper surface of the silicon nitride layer is same as a level of the upper surface of the protection layer 131 formed in the cell active area 110C. Forming the gate capping layer 240 may include removing the silicon nitride layer on the hard mask 210 using a CMP method.

Referring to 20A to 20D, the method of forming a semiconductor device in accordance with some example embodiments of the inventive concepts may include removing a hard mask 210, and forming a masking layer 310 on an entire substrate 100.

The cell gate insulating layer 221 formed on an upper surface and side of the hard mask 210 may be removed. The cell gate insulating layer 221 on an upper surface and side of the hard mask 210 may be removed by removing the hard mask 210. The cell gate insulating layer 221 on an upper surface and side of the hard mask 210, and the hard mask 210 may be removed by a single etching process. A level of the upper surface of the cell gate insulating layer 221 formed on the inner wall of the gate trench GT may be same as a level of the upper surface of the protection layer 131 formed in the cell active area 110C and/or a level of the upper surface of the gate capping layer 240 formed in the gate trench GT.

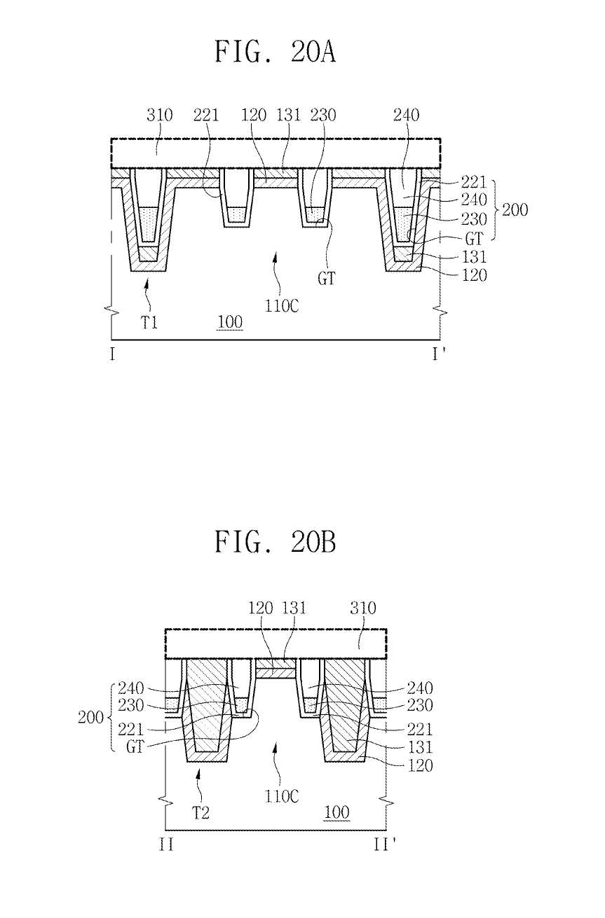

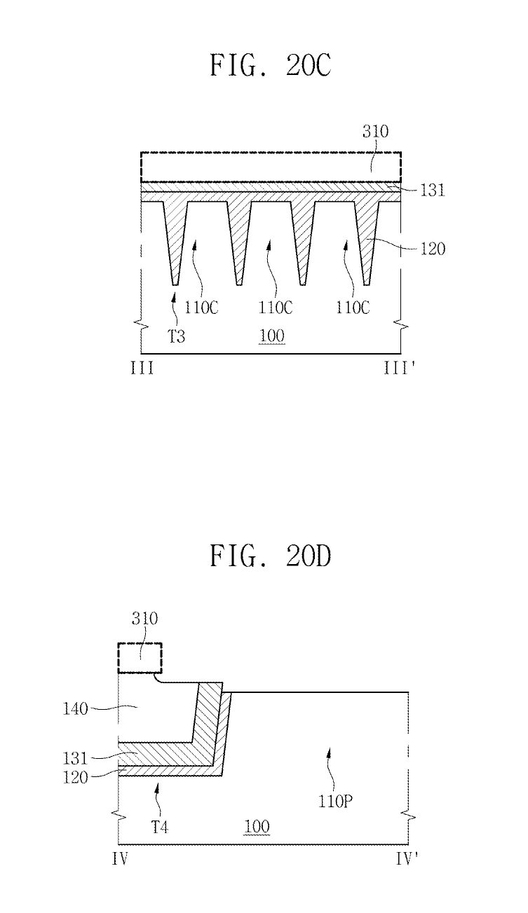

The masking layer 310 may be formed on the substrate 100 in the cell area CA, so that the substrate 100 in the peripheral area PA may be exposed. The masking layer 310 may be formed on a part of the isolating area T4 as shown in FIG. 20D. The masking layer 310 may include a photoresist layer. The substrate 100 in the peripheral active area 110P may be exposed as shown in FIG. 20D by removing the protection layer 131 and the protection layer 120 formed in the peripheral area PA exposed by the masking layer 310. The removal of the protection layer 131 and the protection layer 120 may be performed by an etching process, and as an example, the protection layer 131 formed in the peripheral area PA may be removed by a dry etching process, and then the exposed protection layer 120 may be removed by a wet etching process. In the isolating area T4, the protection layer 120, the protection layer 131, and the trench insulating layer 140 may be formed to have a step height in an area adjacent to the peripheral area PA, in which the masking layer 310 is not formed, smaller than in an area adjacent to the cell area CA by an etching process.

Referring to 16A to 16D, the method of forming a semiconductor device in accordance with some example embodiments of the inventive concepts may include forming the contact pads 510 and contact pads 511 may be formed on the insulating layer 410, on which the storage contacts BC and the source/drain contacts 420 are formed, and the information storage element 500 may be formed in the cell area CA.

FIG. 21 is a schematic view showing a memory module 2100 including at least one of the semiconductor devices in accordance with various example embodiments of the inventive concepts. Referring to FIG. 21, the memory module 2100 may include a memory module substrate 2110, a plurality of memory devices 2120 disposed on the memory module substrate 2110, and a plurality of terminals 2130. The memory module substrate 2110 may include a printed circuit board (PCB) or a wafer. The memory devices 2120 may be one of the semiconductor devices in accordance with various example embodiments of the inventive concepts, or a semiconductor package including one of the semiconductor devices. The plurality of terminals 2130 may include a conductive metal. Each terminal may be electrically connected to each memory device 2120. Since the memory module 2100 includes the semiconductor device having excellent operational reliability, module performance is improved.

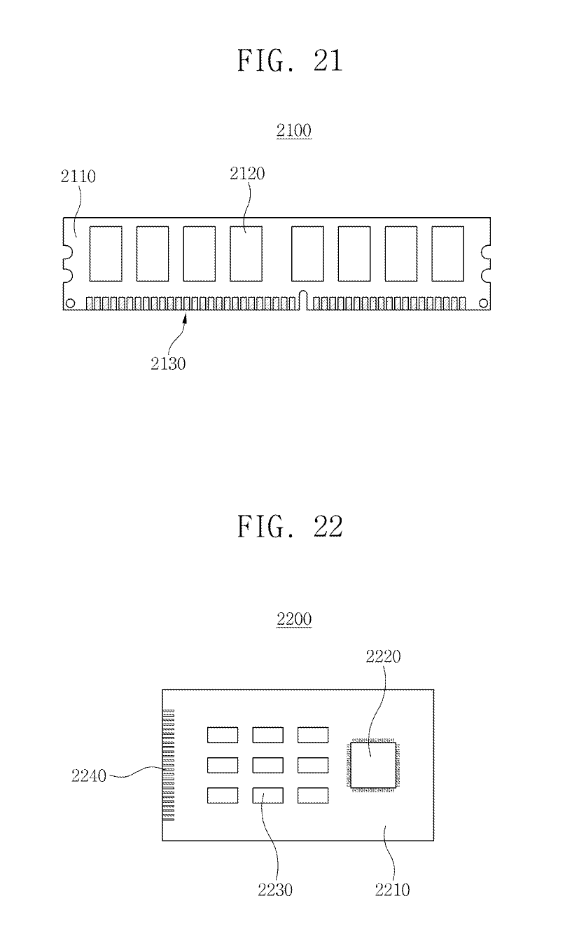

FIG. 22 is a schematic view showing a semiconductor module 2200 including at least one of the semiconductor devices in accordance with various example embodiments of the inventive concepts. Referring to FIG. 22, the semiconductor module 2200 in accordance with some example embodiments of the inventive concepts may include one 2230 of the semiconductor devices in accordance with various example embodiments of the inventive concepts installed on a semiconductor module substrate 2210. The semiconductor module 2200 may further include a microprocessor 2220 installed on the module substrate 2210. Input/output terminals 2240 may be disposed on at least one side of the module substrate 2210.

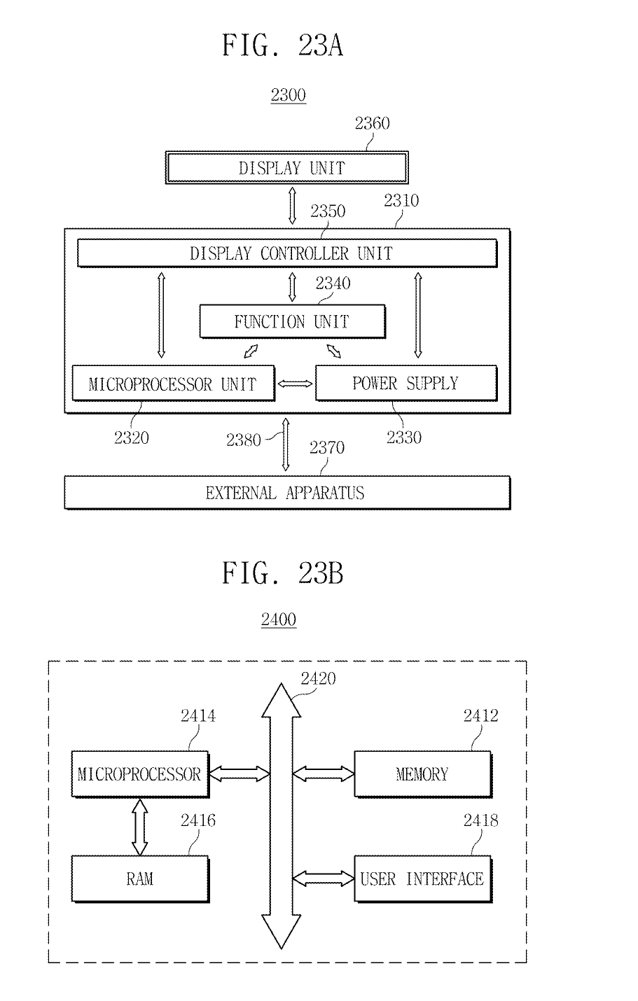

FIG. 23A is a conceptual block diagram showing an electronic system 2300 including at least one of the semiconductor devices in accordance with various example embodiments of the inventive concepts. Referring to FIG. 23, the semiconductor devices in accordance with various example embodiments of the inventive concepts may be applied to the electronic system 2300. The electronic system 2300 may include a body 2310. The body 2310 may include a microprocessor unit 2320, a power supply 2330, a function unit 2340, and/or a display controller unit 2350. The body 2310 may be a system board or a motherboard having a PCB, etc. The microprocessor unit 2320, the power supply 2330, the function unit 2340, and the display controller unit 2350 may be installed or mounted on the body 2310. A display unit 2360 may be disposed on an upper surface of the body 2310 or outside the body 2310. For example, the display unit 2360 may be disposed on a surface of the body 2310, and display an image processed by the display controller unit 2350. The power supply 2330 may receive a constant voltage from an external power supply, divide the voltage into various voltages levels, and supply those voltages to the microprocessor unit 2320, the function unit 2340, the display controller unit 2350, etc. The microprocessor unit 2320 may receive a voltage from the power supply 2330 to control the function unit 2340 and the display unit 2360. The function unit 2340 may perform various functions of the electronic system 2300. For example, when the electronic system 2300 is a mobile electronic product such as a cellular phone, etc., the function unit 2340 may include various components which perform wireless communication functions such as dialing, image output to the display unit 2360, or voice output to a speaker through communication with an external device 2370, and when a camera is included, it may serve as an image processor. In another example embodiment, when the electronic system 2300 is connected to a memory card to expand the capacity, the function unit 2340 may be a memory card controller. The function unit 2340 may exchange signals with the external device 2370 through a wired or wireless communication unit 2380. Further, when the electronic system 2300 requires a Universal Serial Bus (USB) to extend the functions, the function unit 2340 may serve as an interface controller. The semiconductor devices in accordance with various example embodiments of the inventive concepts may be included in at least one of the microprocessor unit 2320 and the function unit 2340.

FIG. 23B is a schematic block diagram showing another electronic system 2400 including at least one of the semiconductor devices in accordance with various example embodiments of the inventive concepts. Referring to FIG. 23, the electronic system 2400 may include at least one of the semiconductor devices in accordance with various example embodiments of the inventive concepts. The electronic system 2400 may be used to manufacture a mobile device or a computer. For example, the electronic system 2400 may include a memory 2412, a microprocessor 2414, a RAM 2416, and a user interface 2418 performing data communication using a bus 2420. The microprocessor 2414 may program and control the electronic system 2400. The RAM 2416 may be used as an operational memory of the microprocessor 2414. For example, the microprocessor 2414 and the RAM 2416 may include at least one of the electrode connection structures in accordance with some example embodiments of the inventive concepts. The microprocessor 2414, the RAM 2416, and/or other components may be assembled within a single package. The user interface 2418 may be used to input data to the electronic system 2400, or output data from the electronic system 2400. The memory system 2412 may store operational codes of the microprocessor 2414, data processed by the microprocessor 2414, or data received from the outside. The memory system 2412 may include a controller and a memory.

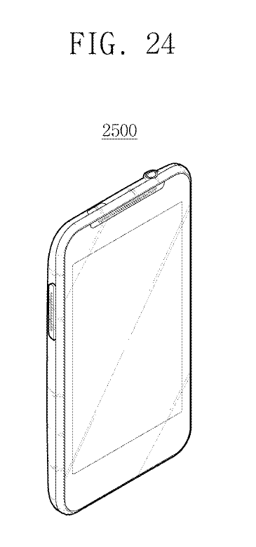

FIG. 24 is a schematic view showing a mobile wireless phone 2500 including at least one of the semiconductor devices in accordance with various example embodiments of the inventive concepts. The mobile wireless phone 2500 may be understood as a tablet PC. Furthermore, at least one of the semiconductor devices in accordance with various embodiments of the inventive concept may be used to a portable computer such as a notebook PC, an MPEG audio layer-3 (MP3) player, an MP4 player, a navigation device, a solid state disk (SSD), a desktop computer, an automobile, and a household appliance, in addition to the tablet PC.

The semiconductor device and the method of manufacturing thereof in accordance with various example embodiments of the inventive concepts may use an insulating layer filling an isolating trench as a protection layer without forming an extra thin layer to protect a cell area, and thus, a process is simple. The method may prevent a stringer caused by a metal thin layer formed in a boundary area between the cell area and the peripheral area, and thus, operational reliability of the semiconductor device may be improved.

The foregoing is illustrative of example embodiments and is not to be construed as limiting thereof. Although a few example have been described, those skilled in the art will readily appreciate that many modifications are possible in example embodiments without materially departing from the novel teachings and advantages. Accordingly, all such modifications are intended to be included within the scope of the inventive concepts as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific example embodiments disclosed, and that modifications to the disclosed example embodiments, as well as other embodiments, are intended to be included within the scope of the appended claims.

What is claimed is:

1. A semiconductor device, comprising:
a substrate including an isolating trench defining active areas;
a gate structure formed in an active area and crossing the isolating trench;
a first protection layer formed on the active area of the substrate; and
a second protection layer formed on the first protection layer,
wherein, in a first isolating area in which the gate structure and the isolating trench cross, the first protection layer is formed on an inner wall and bottom of the isolating trench, and the second protection layer is formed on the first protection layer formed on the bottom of the isolating trench.

2. The semiconductor device according to claim 1, wherein, in the first isolating area, the gate structure completely fills the isolating trench.

3. The semiconductor device according to claim 1, wherein, in a second isolating area in which the gate structure and the isolating trench do not cross, the first protection layer is conformally formed on the inner wall and bottom of the isolating trench, and the second protection layer completely fills the isolating trench.

4. The semiconductor device according to claim 3, wherein a level of an upper surface of the second protection layer in the second isolating area is same as a level of the upper surface of the second protection layer in the active area.

5. The semiconductor device according to claim 1, wherein, in a third isolating area in which the isolating trench is formed to have a width smaller than in the first isolating area, the first protection layer completely fills the isolating trench, and the second protection layer is formed on the first protection layer.

6. The semiconductor device according to claim 5, wherein a level of an upper surface of the first protection layer in the third isolating area is same as a level of the upper surface of the first protection layer in the active area.

7. The semiconductor device according to claim 5, wherein a level of the upper surface of the second protection layer in the third isolating area is same as a level of the upper surface of the second protection layer in the active area.

8. The semiconductor device according to claim 1, wherein, in a fourth isolating area in which the isolating trench is formed to have a width greater than in the first isolating area, the first protection layer is conformally formed on the inner wall and bottom of the isolating trench, and the second protection layer is conformally formed on the first protection layer.

9. The semiconductor device according to claim 8, further comprising a trench insulating layer completely filling the isolating trench in the fourth isolating area.

10. The semiconductor device according to claim 8, wherein a thickness of the second protection layer in the fourth isolating area is different from a thickness of the second protection layer in the active area.

11. The semiconductor device according to claim 1, wherein the gate structure comprises:
gate trenches formed in the active area, and crossing the isolating trench;
a gate line filling a lower portion of the gate trench; and
a gate capping layer filling an upper portion of the gate trench, and
wherein a level of an upper surface of the gate capping layer is same as a level of an upper surface of the second protection layer in the active area.

12. The semiconductor device according to claim 11, wherein the gate structure further comprises a gate insulating layer formed on the substrate exposed on the inner wall and bottom of the gate trench.

13. The semiconductor device according to claim 11, wherein the gate structure further comprises a gate insulating layer comformally formed on the inner wall and bottom of the gate trench.

14. The semiconductor device according to claim 1, wherein the first protection layer is conformally formed on an inner wall and bottom of the isolating trench.

15. A semiconductor device, comprising:
a substrate including a cell area and a peripheral area;
an isolating trench defining a cell active area in the cell area, and a peripheral active area in the peripheral area;
a cell gate structure formed in the cell active area and crossing the isolating trench;
a first protection layer formed on an upper surface of the cell active area, and an inner wall and bottom of the isolating trench;
a second protection layer formed on the first protection layer on the upper surface of the cell active area and the bottom of the isolating trench;
a bit line structure arranged substantially perpendicular to the cell gate structure, and crossing the cell active area; and
a peripheral gate line structure crossing the peripheral active area.

16. The semiconductor device according to claim 14, wherein the bit line structure includes a first conductive layer, a second conductive layer, and a hard mask stacked.

17. The semiconductor device according to claim 15, wherein the first protection layer is conformally formed on an upper surface of the cell active area.

18. A semiconductor device comprising:
a substrate including an isolating trench; and
an insulating layer filling the isolating trench for isolating a cell area from a peripheral area of the substrate, the insulating layer including a first protection layer formed on an inner wall and bottom of the isolating trench, and a second protection layer formed on the first protection layer formed on a bottom of the isolating trench, wherein the insulating layer is a protection layer protecting the cell area from generation of a metal layer in a boundary area between the cell area and the peripheral area.

19. The semiconductor device of claim 18, wherein the first protection layer is conformally formed on an inner wall and bottom of the isolating trench.

20. The semiconductor device of claim 18, further comprising a gate structure crossing the isolating trench.
